(19) United States
(12) Patent Application Publication
(10) Pub. No.: US 2022/0093780 A1
(43) Pub. Date: Mar. 24, 2022

(54) EPITAXIAL STRUCTURE OF GA-FACE GROUP III NITRIDE, ACTIVE DEVICE, AND GATE PROTECTION DEVICE THEREOF

(71) Applicant: CHIH-SHU HUANG, TAIPEI CITY (TW)

(72) Inventor: CHIH-SHU HUANG, TAIPEI CITY (TW)

(21) Appl. No.: 17/457,836

(22) Filed: Dec. 6, 2021

Related U.S. Application Data
(63) Continuation-in-part of application No. 17/017,119, filed on Sep. 10, 2020, now Pat. No. 11,195,943.

(30) Foreign Application Priority Data
Sep. 12, 2019 (TW) 108132995

(51) Int. Cl. H01L 29/778; H01L 29/20; H01L 29/205; H01L 29/423

(52) U.S. Cl. CPC H01L 29/7786; H01L 29/42376; H01L 29/205; H01L 29/2003

(57) ABSTRACT

The present invention relates to an epitaxial structure of Ga-face group III nitride, its active device, and its gate protection device. The epitaxial structure of Ga-face AlGaN/GaN comprises a silicon substrate, a buffer layer (C-doped) on the silicon substrate, an i-GaN (C-doped) layer on the buffer layer (C-doped), an i-Al_{y}GaN buffer layer on the i-GaN (C-doped) layer, an i-GaN channel layer on the i-Al_{y}GaN buffer layer, and an i-AlₓGaN layer on the i-GaN channel layer, where x=0.1˜0.3 and y=0.05˜0.75. By connecting a depletion-mode (D-mode) AlGaN/GaN high electron mobility transistor (HEMT) to the gate of a p-GaN gate enhancement-mode (E-mode) AlGaN/GaN HEMT in device design, the gate of the p-GaN gate E-mode AlGaN/GaN HEMT can be protected under any gate voltage.

### FIELD OF THE INVENTION

The present invention relates generally to an epitaxial structure, and particularly to a novel epitaxial structure of Ga-face group III nitride series capable of blocking the electrons of buffer traps from entering the channel layer, and to the active device and the gate protection device formed by using the epitaxial structure.

### BACKGROUND OF THE INVENTION

According to the prior art, the most common structures to achieve an enhancement-mode AlGaN/GaN high electron mobility transistor (E-mode AlGaN/GaN HEMT) include: 1. Ga-face p-GaN gate E-mode HEMT structure, and 2. N-face AlₓGaN gate E-mode HEMT structure. Nonetheless, as implied by their names, only the gate region will be p-GaN or AlₓGaN.

The most common fabrication method is to use an epitaxial structure and etch p-GaN outside the gate region using dry etching while maintaining the completeness of the thickness of the underlying epitaxial layer. Because if the underlying epitaxial layer is etched too much, two-dimensional electron gas (2DEG) will not be formed at the interface AlGaN/GaN of a Ga-face p-GaN gate E-mode HEMT structure. Thereby, the using dry etching is challenging because the etching depth is hard to control and nonuniformity in thickness still occurs in every epitaxial layer of an epitaxial wafer.

Accordingly, to improve the above drawbacks, the present invention provides a novel epitaxial structure of Ga-face group III nitride, an active device, and a gate protection device formed by using the epitaxial structure.

### SUMMARY

An objective of the present invention is to provide a novel epitaxial structure of Ga-face group III nitride, an active device, and a gate protection device formed by using the epitaxial structure for enabling the gate of a p-GaN gate E-mode AlGaN/GaN HEMT to be protected under any gate voltage. In addition, multiple types of high-voltage and high-speed active devices can be formed on the substrate of the epitaxial structure of Ga-face group III nitride at the same time.

To achieve the above objective, the present invention provides an epitaxial structure of AlGaN/GaN HEMT, which includes a gate protection device of D-mode AlGaN/GaN HEMT. The gate protection device is connected to: 1. the gate of a p-GaN gate E-mode AlGaN/GaN HEMT formed by selective epitaxial growth; or 2. the gate of a p-GaN gate E-mode AlGaN/GaN HEMT formed by dry etching. The epitaxial structure of Ga-face AlGaN/GaN as described above comprises a silicon substrate, a buffer layer (C-doped) on the silicon substrate, an i-GaN (C-doped) layer on the buffer layer (C-doped), an i-Al_{y}GaN buffer layer on the i-GaN (C-doped) layer, an i-GaN channel layer on the i-Al_{y}GaN buffer layer, and an i-AlₓGaN layer on the i-GaN channel layer, where x=0.1˜0.3 and y=0.05˜0.75.

### BRIEF DESCRIPTION OF THE DRAWINGS

FIG. 1 shows distributions of E_{PS} and E_{PZ} in Ga-face and N-face AlGaN/GaN and GaN/InGaN systems in different stains according to the present invention;

FIG. 2 shows a schematic diagram of Ga-face and N-face GaN grown on a substrate;

FIG. 3 shows a schematic diagram of the different locations of 2DEG generated at the junctions between AlGaN and GaN due to different polarization according to the present invention;

FIG. 4A shows a band diagram of a p-GaN layer grown on the epitaxial structure of AlGaN/GaN HEMT according to the present invention;

FIG. 4B to FIG. 4C show the operations of the p-GaN gate E-mode AlGaN/GaN HEMT at a fixed Vd and varying gate voltages Vg according to the present invention;

FIG. 4D shows a cross-section and the equivalent circuits of the gate to the GaN layer according to the present application.

FIG. 4E shows forward voltage/current and reversed voltage/current according to the present application.

FIG. 4F shows a equivalent circuit of the source of a D-mode AlGaN/GaN HEMT connected to the gate of a p-GaN gate E-mode AlGaN/GaN HEMT.

FIG. 4G shows the voltage and current operating curves of the devices shown in the equivalent circuits in FIG. 4E;

FIG. 5A shows an epitaxial structure diagram of the Ga-face AlGaN/GaN HEMT according to the present invention;

FIG. 5B shows an epitaxial structure diagram of the improved Ga-face AlGaN/GaN HEMT according to the present invention;

FIG. 6A and FIG. 6B show cross-sectional views of a SEG p-GaN gate E-mode AlGaN/GaN HEMT using a thin SEG p-GaN gate D-mode AlGaN/GaN HEMT without gate dielectric layer as the gate protection device according to the present invention;

FIG. 7A-1 and FIG. 7A-2 show cross-sectional views of the inverted trapezoidal gate structure for one of the SEG p-GaN gates;

FIG. 7A-3 and FIG. 7A-4 show cross-sectional views of the inverted trapezoidal gate structure and the thin p-GaN gate structure for the SEG p-GaN gates corresponding to FIG. 7A-1 and FIG. 7A-2 are fabricated;

FIG. 7B shows a cross-sectional view after the drain and source metals corresponding to FIG. 7A-3 and FIG. 7A-4 are fabricated;

FIG. 7C-1 shows a cross-sectional view of dry-etching to the high-resistivity i-GaN buffer layer (C-doped) for isolating devices;

FIG. 7C-2 shows a cross-sectional view of adopting a plurality of energy destructive ion implantations to the high-resistivity i-GaN buffer layer (C-doped) for isolating devices;

FIG. 7D-1 and FIG. 7D-2 show cross-sectional views of forming the gate metal and the bonding pads or interconnection metals for drain and source corresponding to FIG. 7C-1 and FIG. 7C-2;

FIG. 7E-1 and FIG. 7E-2 show cross-sectional views of forming and patterning a passivation layer for exposing the drain and source bonding pad regions corresponding to FIG. 7D-1 and FIG. 7D-2;

FIG. 7F-1 and FIG. 7F-2 show cross-sectional views of the D-mode AlGaN/GaN HEMT after the gate field-plate metal is fabricated corresponding to FIG. 7E-1 and FIG. 7E-2;

FIG. 7G shows a top view of the SEG p-GaN gate E-mode AlGaN/GaN HEMT using a D-mode AlGaN/GaN HEMT without gate dielectric layer as the gate protection device;

FIG. 8A-1 and FIG. 8A-2 show cross-sectional views of the etched p-GaN gate E-mode AlGaN/GaN HEMT using a thin etched p-GaN gate D-mode AlGaN/GaN HEMT without gate dielectric layer as the gate protection device;

FIG. 9A-1 and FIG. 9A-2 show cross-sectional views of fabricating the gate structure for one of the etched p-GaN gates;

FIG. 9A-3 and FIG. 9A-4 show cross-sectional views of fabricating the etched p-GaN gate structure and thin etched p-GaN gate structure for the etched p-GaN gates;

FIG. 9B to FIG. 9F-2 show cross-sectional views of fabricating the etched p-GaN gate E-mode AlGaN/GaN HEMT using a thin p-GaN gate D-mode AlGaN/GaN HEMT without gate dielectric layer as the gate protection device;

FIG. 9G shows a top view of the etched p-GaN gate E-mode AlGaN/GaN HEMT using the thin p-GaN gate D-mode AlGaN/GaN HEMT without gate dielectric layer as the gate protection device;

FIG. 10A-1 and FIG. 10A-2 show cross-sectional views of the SEG p-GaN gate E-mode AlGaN/GaN HEMT using a fluorine lightly implanted D-mode AlGaN/GaN HEMT without gate dielectric layer as the gate protection device;

FIG. 11A-1 and FIG. 11A-2 show cross-sectional views for fabricating the SEG p-GaN gate;

FIG. 11B shows a cross-sectional view after the drain and source metals corresponding to FIG. 11A-2 are fabricated;

FIG. 11C shows a cross-sectional view after fluorine implantation corresponding to FIG. 11B are fabricated;

FIG. 11D-1 shows a cross-sectional view of dry-etching to the high-resistivity i-GaN buffer layer (C-doped) for isolating devices;

FIG. 11D-2 shows a cross-sectional view of adopting a plurality of energy destructive ion implantations to the high-resistivity i-GaN buffer layer (C-doped) for isolating devices;

FIG. 11E-1 and FIG. 11E-2 show cross-sectional views of forming the gate metal and the bonding pads or interconnection metals for drain and source corresponding to FIG. 11D-1 and FIG. 11D-2;

FIG. 11F-1 and FIG. 11F-2 show cross-sectional views of forming and patterning a passivation layer for exposing the drain and source bonding pad regions corresponding to FIG. 11E-1 and FIG. 11E-2;

FIG. 11G-1 and FIG. 11G-2 show cross-sectional views of SEG p-GaN gate E-mode AlGaN/GaN HEMT using a fluorine lightly implanted D-mode AlGaN/GaN HEMT without gate dielectric layer as the gate protection device after the gate field-plate metal is fabricated corresponding to FIG. 11F-1 and FIG. 11F-2;

FIG. 11H shows a top view of the SEG p-GaN gate E-mode AlGaN/GaN HEMT using a fluorine lightly implanted D-mode AlGaN/GaN HEMT without gate dielectric layer as the gate protection device;

FIG. 12A-1 and FIG. 12A-2 show cross-sectional views of the etched p-GaN gate E-mode AlGaN/GaN HEMT using a fluorine lightly implanted D-mode AlGaN/GaN HEMT without gate dielectric layer as the gate protection device;

FIG. 13A-1 and FIG. 13A-2 show cross-sectional views for fabricating the etched p-GaN gate;

FIG. 13B shows a cross-sectional view after the drain and source metals corresponding to FIG. 13A-2 are fabricated;

FIG. 13C shows a cross-sectional view after fluorine lightly implantation corresponding to FIG. 13B are fabricated;

FIG. 13D-1 shows a cross-sectional view of dry-etching to the high-resistivity i-GaN buffer layer (C-doped) for isolating devices;

FIG. 13D-2 shows a cross-sectional view of adopting multiple-energy destructive ion implantation to the high-resistivity i-GaN buffer layer (C-doped) for isolating devices;

FIG. 13E-1 and FIG. 13E-2 show cross-sectional views of forming the gate metal and the bonding pads or interconnection metals for drain and source corresponding to FIG. 13D-1 and FIG. 13D-2;

FIG. 13F-1 and FIG. 13F-2 show cross-sectional views of forming and patterning a passivation layer for exposing the drain and source bonding pad regions corresponding to FIG. 13E-1 and FIG. 13E-2;

FIG. 13G-1 and FIG. 13G-2 show cross-sectional views of the fluorine lightly implanted D-mode AlGaN/GaN HEMT after the gate field-plate metal is fabricated corresponding to FIG. 13F-1 and FIG. 13F-2;

FIG. 13H shows a top view of SEG p-GaN gate E-mode AlGaN/GaN HEMT using a fluorine lightly implanted D-mode AlGaN/GaN HEMT without gate dielectric layer as the gate protection device;

FIG. 14A-1 and FIG. 14A-2 show cross-sectional views of the SEG p-GaN gate E-mode AlGaN/GaN HEMT using a thin SEG p-GaN gate D-mode AlGaN/GaN HEMT without gate dielectric layer as the gate protection device cascading to a D-mode AlGaN/GaN HEMT with gate dielectric layer;

FIG. 15A-1 shows a cross-sectional view of dry-etching to the high-resistivity i-GaN buffer layer (C-doped) for isolating devices and forming the inverted trapezoidal gate structure for the SEG p-GaN gate and the drain and source metals;

FIG. 15A-2 shows a cross-sectional view of adopting multiple-energy destructive ion implantation to the high-resistivity i-GaN buffer layer (C-doped) for isolating devices and forming the inverted trapezoidal gate structure for the SEG p-GaN gate and the drain and source metals;

FIG. 15B-1 and FIG. 15B-2 show cross-sectional views of forming the gate metal and the bonding pads or interconnection metals for drain and source corresponding to FIG. 15A-1 and FIG. 15A-2;

FIG. 15C-1 and FIG. 15C-2 show cross-sectional views of forming and patterning a passivation layer for exposing the drain and source bonding pad regions corresponding to FIG. 15B-1 and FIG. 15B-2;

FIG. 15D-1 and FIG. 15D-2 show cross-sectional views after the gate field-plate metal is fabricated corresponding to FIG.15C-1 and FIG. 15C-2;

FIG. 15E shows a top view corresponding to FIG. 15A-1 and FIG. 15A-2;

FIG. 16A-1 and FIG. 16A-2 show cross-sectional views of the etched p-GaN gate E-mode AlGaN/GaN HEMT using a thin p-GaN gate D-mode AlGaN/GaN HEMT without gate dielectric layer as the gate protection device cascading to a D-mode AlGaN/GaN HEMT with gate dielectric layer;

FIG. 17A-1 shows a cross-sectional view of dry-etching to the high-resistivity i-GaN buffer layer (C-doped) for isolating devices and forming the structure of the etched p-GaN gate and the drain and source metals;

FIG. 17A-2 shows a cross-sectional view of adopting multiple-energy destructive ion implantation to the high-resistivity i-GaN buffer layer (C-doped) for isolating devices and forming the structure of the etched p-GaN gate and the drain and source metals;

FIG. 17B-1 and FIG. 17B-2 show cross-sectional views of forming the gate metal and the bonding pads or interconnection metals for drain and source corresponding to FIG. 17A-1 and FIG. 17A-2;

FIG. 17C-1 and FIG. 17C-2 show cross-sectional views of forming and patterning a passivation layer for exposing the drain and source bonding pad regions corresponding to FIG. 17B-1 and FIG. 17B-2;

FIG. 17D-1 and FIG. 17D-2 show cross-sectional views after the gate field-plate metal is fabricated corresponding to FIG. 17C-1 and FIG. 17C-2;

FIG. 17E shows a top view of the etched p-GaN gate E-mode AlGaN/GaN HEMT using a thin p-GaN gate D-mode AlGaN/GaN HEMT without gate dielectric layer as the gate protection device cascading to a D-mode AlGaN/GaN HEMT with gate dielectric layer corresponding to FIG. 17A-1 and FIG. 17A-2;

FIG. 18A-1 and FIG. 18A-2 show cross-sectional views of the SEG p-GaN gate E-mode AlGaN/GaN HEMT using a fluorine lightly implanted D-mode AlGaN/GaN HEMT without gate dielectric layer as the gate protection device cascading to a D-mode AlGaN/GaN HEMT with gate dielectric layer;

FIG. 18B shows a top view of the SEG p-GaN gate E-mode AlGaN/GaN HEMT using a fluorine lightly implanted D-mode AlGaN/GaN HEMT without gate dielectric layer as the gate protection device cascading to a D-mode AlGaN/GaN HEMT with gate dielectric layer corresponding to FIG. 18A-1 and FIG. 18A-2;

FIG. 19A-1 and FIG. 19A-2 show cross-sectional views of the etched p-GaN gate E-mode AlGaN/GaN HEMT using a fluorine lightly implanted D-mode AlGaN/GaN HEMT without gate dielectric layer as the gate protection device cascading to a D-mode AlGaN/GaN HEMT with gate dielectric layer;

FIG. 19B shows a top view of the etched p-GaN gate E-mode AlGaN/GaN HEMT using a fluorine lightly implanted D-mode AlGaN/GaN HEMT without gate dielectric layer as the gate protection device cascading to a D-mode AlGaN/GaN HEMT with gate dielectric layer corresponding to FIG. 19A-1 and FIG. 19A-2;

FIG. 20 shows an equivalent circuit of a D-mode AlGaN/GaN HEMT without gate dielectric layer connecting to a p-GaN gate E-mode AlGaN/GaN HEMT and cascading to a D-mode AlGaN/GaN HEMT with gate dielectric layer.

### DETAILED DESCRIPTION

FIG. 1 shows distributions of E_{PS} and E_{PZ} in Ga-face and N-face AlGaN/GaN and GaN/InGaN systems in different stains according to the present invention, where E_{PS} is the spontaneous polarization (the polarization of the material) while E_{PZ} is the piezoelectric polarization (the polarization formed by the piezoelectric effect of strain). Thereby, E_{PS} is determined by the epitaxial layers while E_{PZ} is determined by the piezoelectric effect of strain.

In the AlGaN/GaN system, the value of E_{PZ} is negative when AlGaN is under tensile strain and is positive when AlGaN is under compressive strain. Contrarily, in the GaN/InGaN system, the signs for the values of E_{PZ} are opposite. In addition, according to Reference [2], it is known that, firstly, in the AlGaN/GaN system, the polarization is determined by E_{SP}, and secondly, in the GaN/InGaN system, the polarization is determined by E_{PZ}.

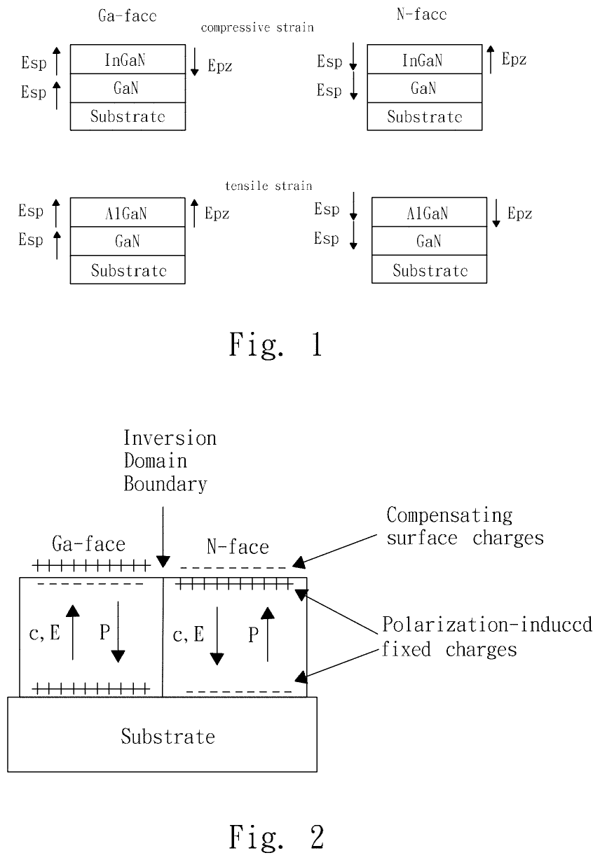

As shown in FIG. 2, P is spontaneous polarization and E is the corresponding electric field. In GaN, the Ga-face (N-face) polarization is determined when the Ga atom (N atom) layer of the Ga-N dual-layer faces the surface of epitaxy. As shown in the figure, a schematic diagram of Ga-face and N-face GaN grown on a substrate is illustrated. If it is Ga-face polarization, the internal electric field is away from the substrate and pointing to the surface. Thereby, the polarization is opposite to the direction of the internal electric field. Consequently, the polarization will cause negative charges to accumulate on the surface of lattice and positive charges to accumulate at the junction with the substrate. On the contrary, if it is N-face polarization, the locations of charge accumulation are swapped and the direction of internal electric field is opposite.

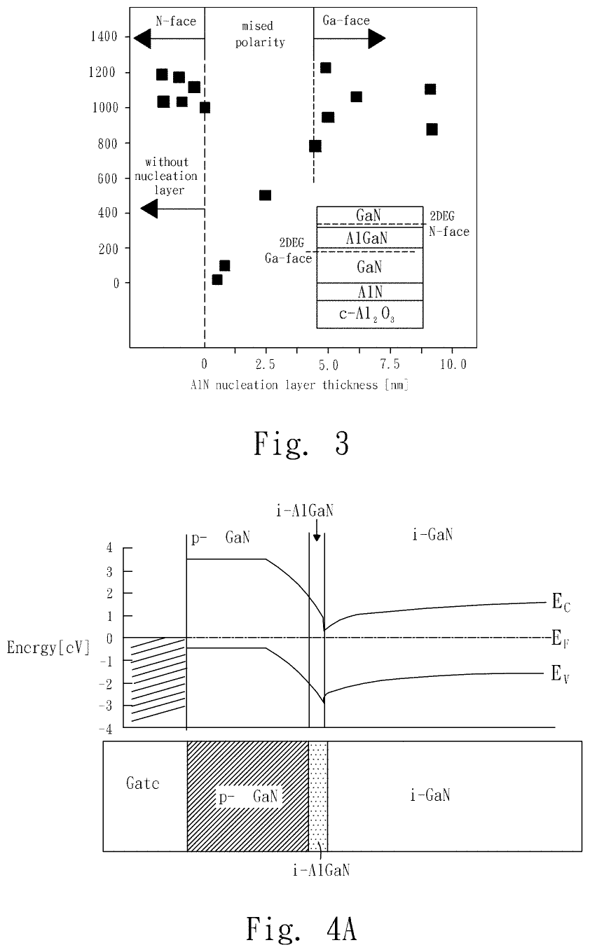

For an AlGaN/GaN HEMT, the most important thing is how the Ga- and N-face polarization influence the device characteristics. FIG. 3 shows a schematic diagram of the different locations of 2DEG generated at the junctions between AlGaN and GaN due to different polarization. In the Ga-face structure, 2DEG exists at the AlGaN/GaN interface while in the N-face structure, 2DEG exists at the GaN/AlGaN interface. The existence of 2DEG indicates accumulation of positive polarization charges at the interface and the 2DEG itself is just the accumulation of free electrons for compensating the polarization charges.

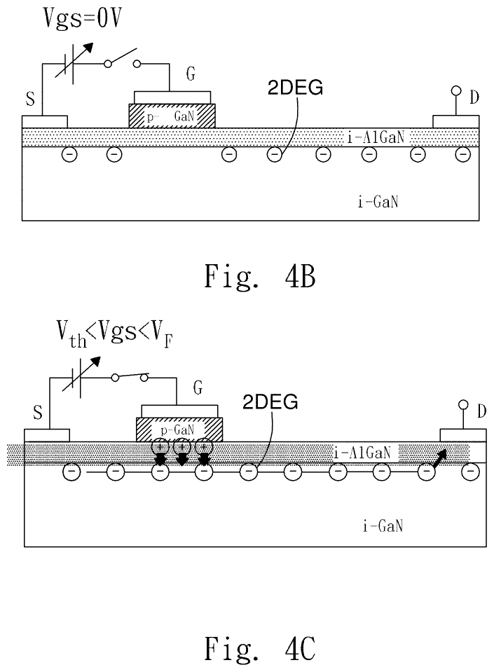

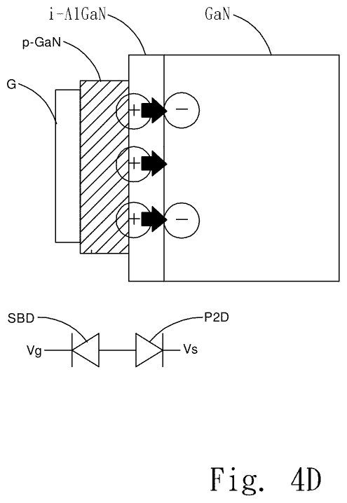

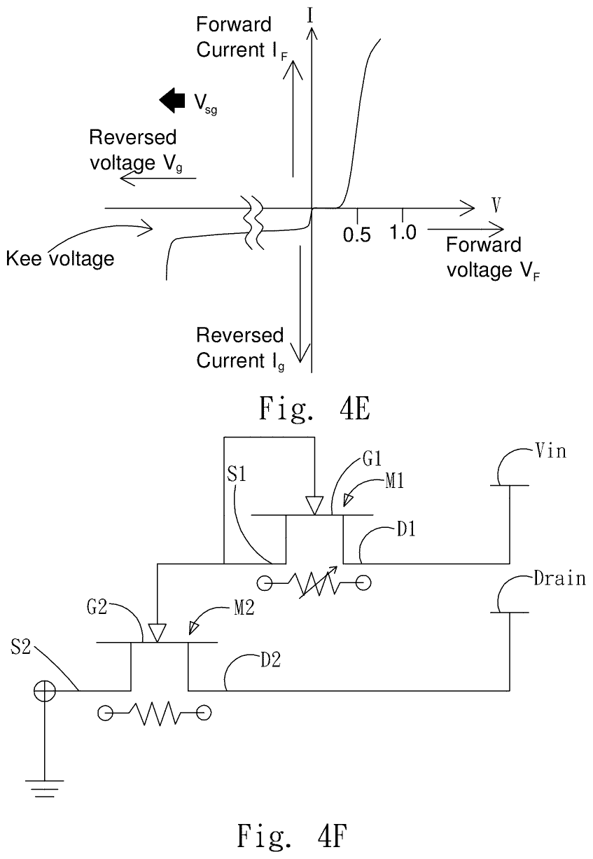

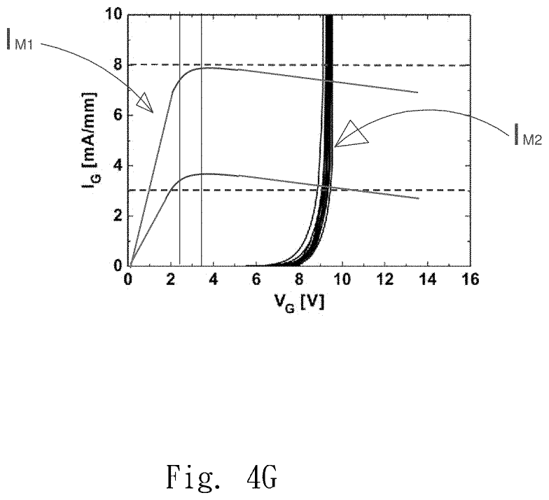

As shown in FIG. 4A to FIG. 4C, the principle of p-GaN gate E-mode AlGaN/GaN HEMT can be viewed from two perspectives. First, by viewing from the polarization electric field, after a p-GaN layer is grown on the epitaxial structure of AlGaN/GaN HEMT, this p-GaN layer will generate a polarization electric field to deplete the 2DEG in the i-GaN channel layer. Secondly, by viewing from the energy band, as shown in FIG. 4A, after a p-GaN layer is grown on the epitaxial structure of AlGaN/GaN HEMT, this p-GaN layer will raise the energy band of the barrier layer i-AlGaN. Thereby, the original potential well at the i-AlGaN/i-GaN junction will be raised above the Fermi energy level, and hence disabling 2DEG from forming.

As shown in FIG. 4B, as the voltage of the p-type gate G is less than or equal to 0, the 2DEG below is completely depleted. Thereby, the current from the drain D cannot pass the channel to reach the source S.

In addition, as shown in the equivalent circuit diagram of FIG. 4D, the gate G of the p-GaN gate E-mode AlGaN/GaN HEMT versus the source S can be viewed as one Schottky diode SBD and one P-type to 2DEG diode P2D connected back-to-back.

When a Vgs is given the SBD in a reversely biased state and the P 2D in a forward biased state, VF is defined as Vgs=V(knee voltage) of SBD+Vf of P2D.

As shown in FIG. 4C, as the voltage of the p-type gate G is greater than 0, the potential well at the i-AlGaN/i-GaN junction is suppressed below the Fermi energy level. Thereby, electrons will refill the potential well below and forming 2DEG. When the 2DEG is recovered completely, this positive voltage is defined as the threshold voltage Vth. At this moment, the channel is turned on again and the current from the drain D can pass the channel to reach the source S.

It is very important to note that

1. When a Vgs is given, the SBD is reversely biased, thereby, SBD is in a reversely biased state.

2. When Vgs is greater than Vth and less than VF there will still be holes in the p-type gate G injection into the channel and recombine with the 2DEG electrons which will result with a very small gate current Igs. It is to be note that when Vgs is increased ↑, it will be caused that Igs is increased ↑ according to the SBD reversed biased characteristics.

3. Igs is a positive ratio of the p-type gate width (Wg), which means when Wg is increased ↑, Igs is increased ↑ at the mean time.

Thereby, when Vgs is greater than VF, the SBD between the gate G and the source S will be reversely punched through. Massive holes will be injected into the channel layer and making the gate leakage current increase rapidly. Hence, the transistor can no longer operate in the desired condition. Accordingly, the limited value of Vgs is always the shortcoming of a p-GaN gate E-mode AlGaN/GaN HEMT. In general, due to different epitaxy and process conditions, Vgs(max) is around 5-10y. Since the gate trigger voltage of a commercial power control IC is 9˜18V, the Schottky gate of the p-GaN gate E-mode AlGaN/GaN HEMT will be punched through directly by the massive gate leakage current Ig generated by the gate trigger voltage and leading to irreversible malfunction of the p-GaN gate E-mode AlGaN/GaN HEMT.

To solve the above problem, as shown in the equivalent circuits in FIG. 4F and, the source of a D-mode AlGaN/GaN HEMT is connected to the gate of a p-GaN gate E-mode AlGaN/GaN HEMT. The source and the gate of the D-mode AlGaN/GaN HEMT M1 are connected electrically using a fabrication method. In other words, the gate G and the source S are shorted (Vgs=0V). Then the D-mode AlGaN/GaN HEMT M1 with Vgs=0V acts as the gate protection device for the p-GaN gate E-mode AlGaN/GaN HEMT M2.

FIG. 4G corresponds to the operating principle and steps of the devices in FIG. 4F. First (Step 1), the p-GaN gate E-mode AlGaN/GaN HEMT M2 must be operated in the condition of Vgs greater than or close to VF, when Igs (the p-GaN gate leakage current) is created, it will turn on the D-mode AlGaN/GaN HEMT M1 at Vgs=0V. Thereby, the Ids of the D-mode AlGaN/GaN HEMT M1 will start to rise (Step 2). When the Ids of the D-mode AlGaN/GaN HEMT M1 has risen to the saturation current Idsat (Step 3), the Igs of the p-GaN gate E-mode AlGaN/GaN HEMT M2 will be fixed to Igs(M2)=Idsat(M1). Thereby, the Vgs of the p-GaN gate E-mode AlGaN/GaN HEMT M2 will be locked to the Vgs when Igs(M2)=Idsat(M1). When the Vin of the D-mode AlGaN/GaN HEMT M1 continues to increase (Step 4), since the Vgs of the p-GaN gate E-mode AlGaN/GaN HEMT M2 is locked, Vin=Vds(M1)+Vgs(M2). Thereby, the p-GaN gate E-mode AlGaN/GaN HEMT M2 will be protected. It is to be note that Idsat(M1) had to be very well controlled by process to fit a desired Igs(M2) in real application, because this Idsat(M1) will cause gate trigger losses for PWM operation. Another important thing is that Idsat(M1) settings also changes when the p-type gate width (Wg) changes.

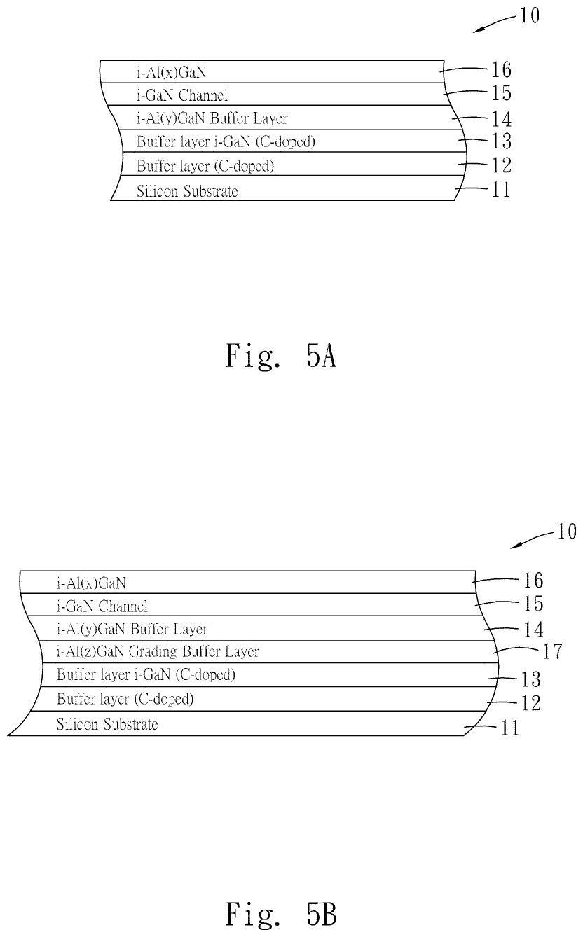

FIG. 5A shows an epitaxial structure diagram of the Ga-face AlGaN/GaN HEMT according to the present invention. This epitaxial structure comprises, in order, a silicon substrate 11, a buffer layer (C-doped) 12, an i-GaN buffer layer (C-doped) 13, an i-Al_{y}GaN buffer layer 14, an i-GaN channel layer 15, and an i-AlₓGaN layer 16. The buffer layer (C-doped) 12 is disposed on the silicon substrate 11. This epitaxial structure includes the i-Al_{y}GaN buffer layer 14, which is mainly used for blocking the electrons of the buffer traps from entering the channel layer and thus avoiding current collapse of the device. FIG. 5B shows another epitaxial structure diagram of the Ga-face AlGaN/GaN HEMT according to the present invention. To avoid the lattice mismatch problem if the i-Al_{y}GaN buffer layer 14 is grown directly on the i-GaN layer (C-doped) 13 as shown in FIG. 5A, an i-Al_{z}GaN grading buffer layer 17 is added.

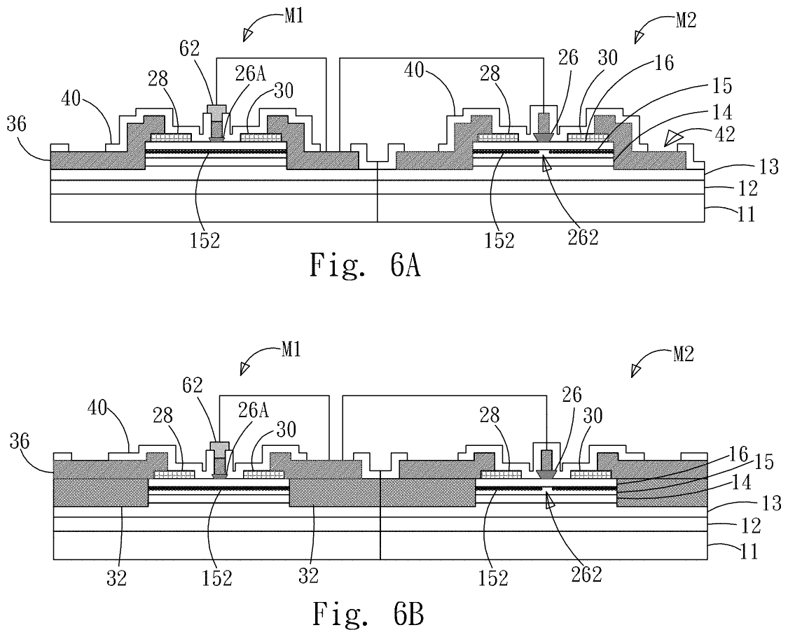

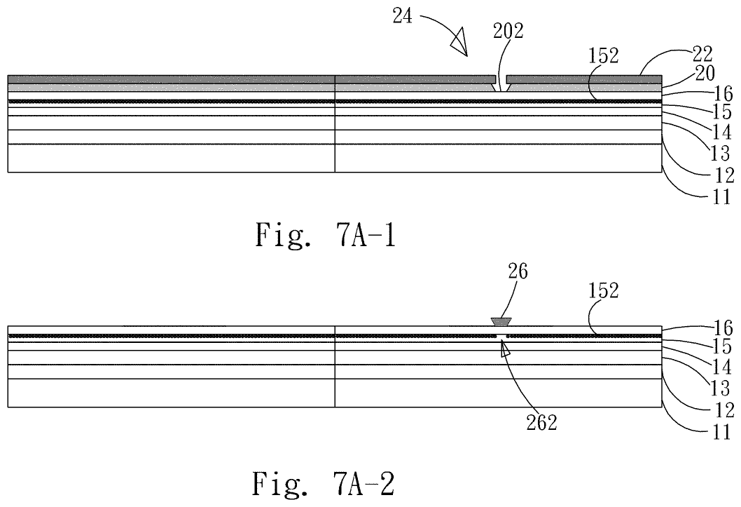

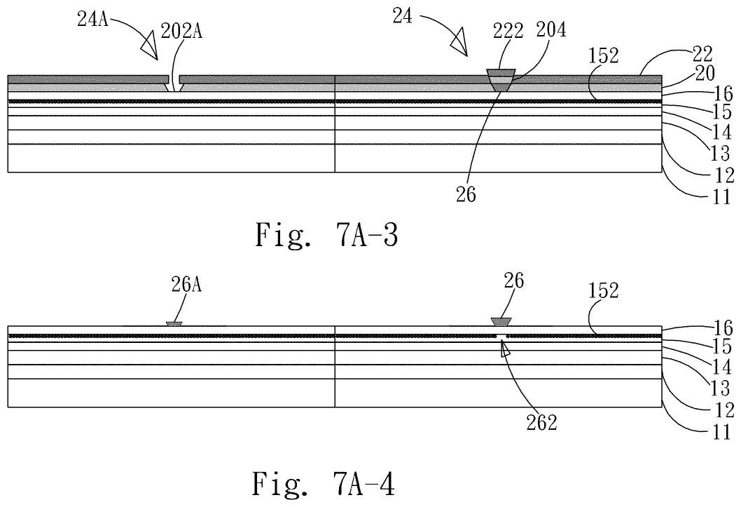

The present invention uses the D-mode AlGaN/GaN HEMT M1 at Vgs=0V as the gate protection device for the p-GaN gate E-mode AlGaN/GaN HEMT M2. Thereby, a selective epitaxial growth (SEG) p-GaN gate is formed on the epitaxial structure according to the present invention for forming an SEG p-GaN gate E-mode AlGaN/GaN HEMT. The present invention adopts an inverted trapezoidal gate structure 26 (as shown in FIG. 6A) and uses SEG for growing p-type GaN for the gate of an AlGaN/GaN D-Mode HEMT and the anode of an AlGaN/GaN SBD. Thanks to the region of p-type GaN (the inverted trapezoidal gate structure 26), the 2DEG below the region will be depleted. Thereby, a p-GaN gate E-mode AlGaN/GaN HEMT can be fabricated. The p-type GaN inverted trapezoidal gate structure 26 is a gate structure. Alternatively, after a p-type epitaxial layer is grown on the epitaxial structure according to the present invention, the dry etching method is adopted to etch and form the p-GaN gate (etched p-GaN gate E-mode AlGaN/GaN HEMT). Accordingly, there are two types of p-GaN gate E-mode AlGaN/GaN HEMT, including the SEG p-GaN gate E-mode AlGaN/GaN HEMT and the etched p-GaN gate E-mode AlGaN/GaN HEMT.

Embodiment 1: An SEG p-GaN gate E-mode AlGaN/GaN HEMT using a SEG p-GaN gate D-mode AlGaN/GaN HEMT without gate dielectric layer as the gate protection device. It is to be note that this is dual SEG process, the thickness of the thin p-GaN gate structure 26A is very thin for the SEG p-GaN gate D-mode AlGaN/GaN HEMT, the purpose of the thin SEG p-GaN gate 26 A is to weaken the 2DEG beneath the thin SEG p-GaN gate 26A in order to get a smaller Idsat per unit of gate width at Vgs=0V.

As shown in FIG. 6A and FIG. 6B, the characteristics of the SEG p-GaN gate E-mode AlGaN/GaN HEMT using a thin SEG p-GaN gate D-mode AlGaN/GaN HEMT without gate dielectric layer as the gate protection device according to the present invention include the epitaxial structure of AlGaN/GaN designed according to the present invention and a p-GaN inverted trapezoidal gate structure 26 located on a first i-AlₓGaN layer. Although the 2DEG is formed at the junction i-AlₓGaN/i-GaN of the i-GaN channel layer 15, due to the existence of the p-GaN inverted trapezoidal gate structure 26, the 2DEG below the p-GaN inverted trapezoidal gate structure 26 in the i-GaN channel layer 15 will be depleted. FIG. 6A and FIG. 6B are schematic diagrams after device fabrication using different device isolation processes. In FIG. 6B multiple-energy destructive ion implantation is adopted. In general, heavy atoms such as boron or oxygen atoms are used for isolating devices. In FIG. 6A, dry etching to the highly resistive i-GaN buffer layer (C-doped) can be adopted for isolating devices.

The SEG p-GaN gate E-mode AlGaN/GaN HEMT using a thin SEG p-GaN gate D-mode AlGaN/GaN HEMT without gate dielectric layer as the gate protection device according to the present invention comprises the epitaxial structure of AlGaN/GaN designed according to the present invention and is divided into a left region and a right region. In the left region, a thin SEG p-GaN gate D-mode AlGaN/GaN HEMT M1 without gate dielectric layer is formed. The thin SEG p-GaN gate D-mode AlGaN/GaN HEMT M1 includes the thin p-GaN gate structure 26A. In the right region, an SEG p-GaN gate E-mode AlGaN/GaN HEMT M2 is formed. This SEG p-GaN gate E-mode AlGaN/GaN HEMT M2 includes a p-GaN inverted trapezoidal gate structure 26. In addition, although the 2DEG is formed at the junction i-AlₓGaN/i-GaN of the i-GaN channel layer 15, due to the existence of the p-GaN inverted trapezoidal gate structure 26, the 2DEG below the p-GaN inverted trapezoidal gate structure 26 in the i-GaN channel layer 15 will be depleted, giving a depletion region 262 without 2DEG.

In the following, the fabrication method for the present embodiment will be described. Nonetheless, a person having ordinary skill in the art should know that the present embodiment and its metal layout is not limited to the fabrication method.

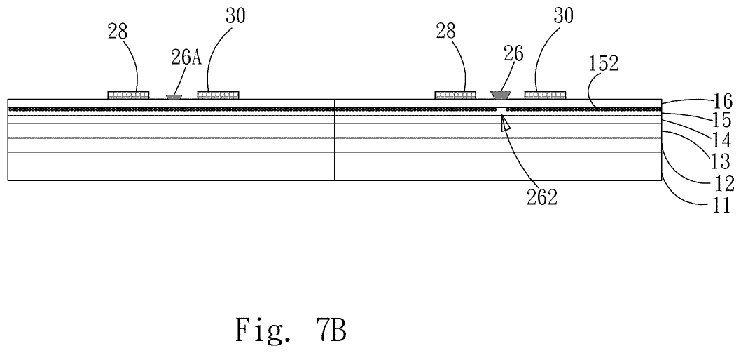

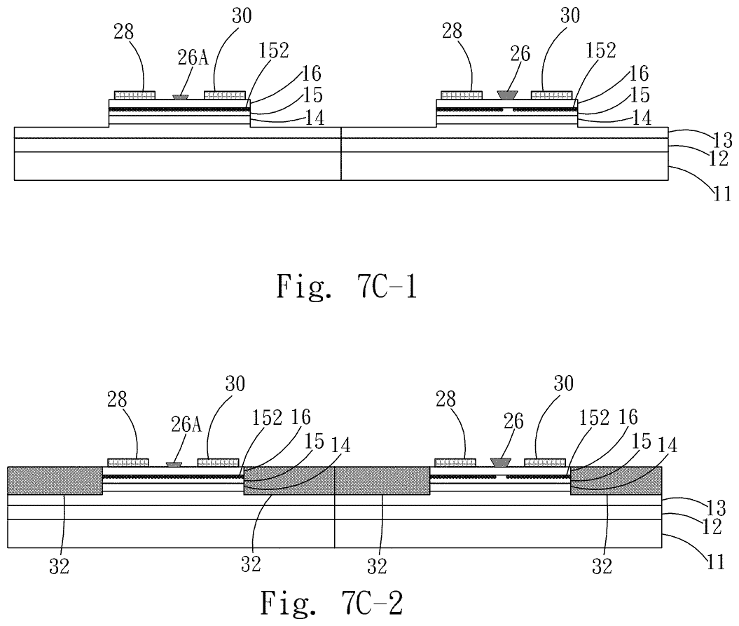

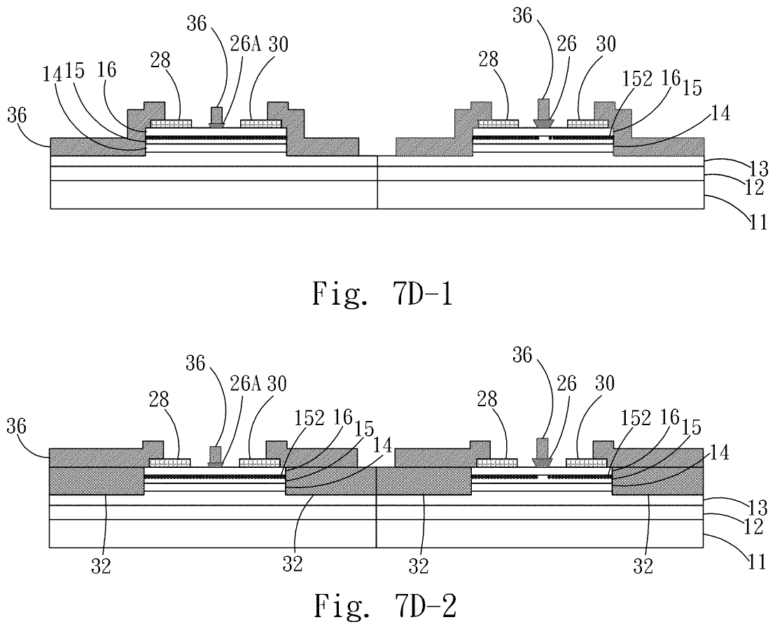

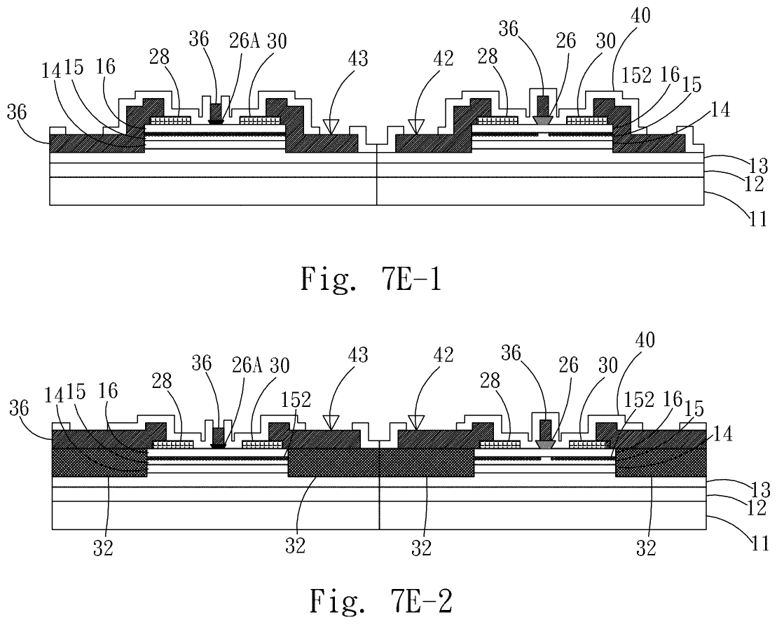

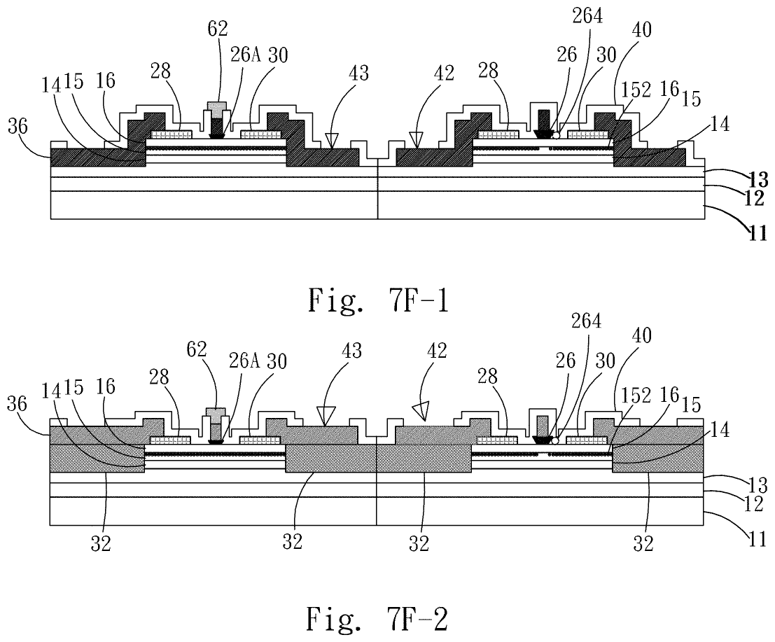

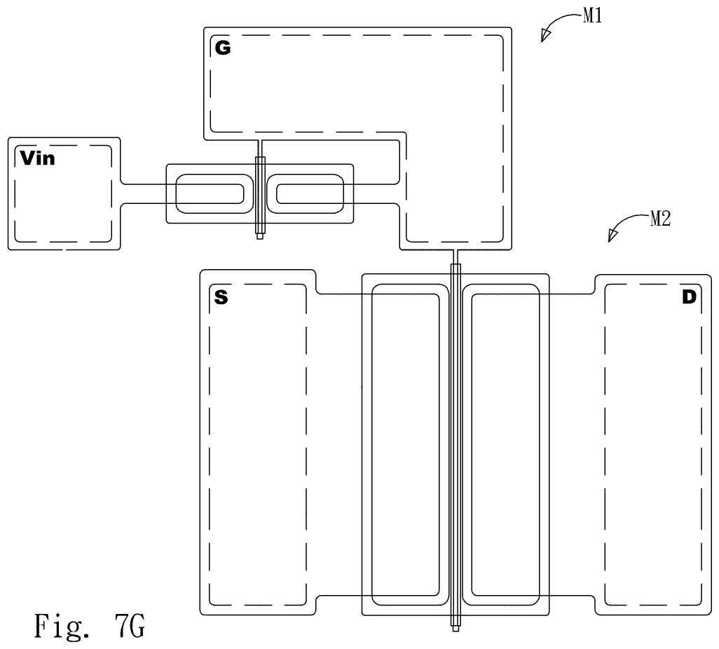

Step S11: Pattern the silicon dioxide mask layer 20. First, as shown in FIG. 7A-1, deposit a silicon dioxide mask layer 20 on the epitaxial structure of Ga-face AlGaN/GaN according to the present invention using plasma-enhanced chemical vapor deposition (PECVD) with a thickness of around 100-200 nm. Next, define the gate SEG region 24 by using photoresist and exposure method. Finally, the silicon dioxide mask layer 20 in the region 24 is etched by a wet etching method using buffered oxide etchant (BOE) to expose the surface of the epitaxy. Then, the photoresist 22 is stripped using stripper. Because the wet etching is isotropic, in addition to etching downward, lateral etching will occur concurrently. Thereby, the opening 202 of the silicon dioxide mask layer 20 in the right p-GaN SEG region 24 will form an inverted trapezoidal structure.

Step S12: Form the p-GaN inverted trapezoidal gate structure 26 using SEG. First, p-GaN SEG is performed using metal-organic chemical vapor deposition (MOCVD) and only the exposed surface of the epitaxy can grow p-GaN. Because the growth of p-GaN in MOCVD is also isotropic, in addition to growing upward, lateral growth will occur concurrently and thus forming an inverted trapezoidal structure of p-GaN, which is just the p-GaN inverted trapezoidal gate structure 26. Finally, the silicon dioxide mask layer 20 is etched by a wet etching method using BOE and forming the structure shown in FIG. 7A-2.

Then, because the right p-GaN SEG region 24 occupies only a small portion of the whole epitaxy wafer, the loading effect will occur easily. Namely, the growth rate on the defined region for p-GaN is three to four times the growth rate on the general surface. Thereby, the p-type doping concentration in p-GaN will be equal to 1/3 to 1/4 of the expected.

Step S13: Repeat S11 and S12 again to form the thin p-GaN on the thin SEG p-GaN gate D-mode AlGaN/GaN HEMT without gate dielectric layer. FIG. 7A-3 and FIG. 7A-4; The left p-GaN SEG region 24A also occupies only a small portion of the whole epitaxy wafer to form the thin p-GaN gate structure 26A while an opening 202A of the silicon dioxide mask layer 20 is formed in the left p-GaN SEG region 24A. Further, the silicon dioxide mask layer 20 and the photoresistor 22 are split by the p-GaN gate structure 26, thereby, a split mask layer 204 and a split photoresistor 222 are formed on the p-GaN gate structure 26.

Step S14: Form the drain ohmic contact 30 and the source ohmic contact 28. A metal layer, for example, a general Ti/Al/Ti/Au or Ti/Al/Ni/Au metal layer, is deposited on the epitaxy wafer using metal vapor deposition. Then a metal lift-off method is adopted to pattern the deposited metal layer for forming the drain and source electrodes on the epitaxy wafer. Afterwards, a thermal treatment is performed at 700˜900° C. for 30 seconds to make the drain and source electrodes become ohmic contacts 30, 28, as shown in FIG. 7B. Wherein the 2DEG 152 below the p-GaN inverted trapezoidal gate structure 26 in the i-GaN channel layer 15 will be depleted, giving a depletion region 262 without 2DEG 152, but the 2DEG 152 below the thin p-GaN gate structure 26A is kept without depletion.

Step S15: Perform device isolation process. In this step, a plurality of energy destructive ion implantations 32 are adopted. In general, heavy atoms such as boron or oxygen atoms are used for isolating devices, as shown in FIG. 7C-2. Alternatively, dry etching to the highly resistive i-GaN buffer layer (C-doped) can be adopted for isolating devices, as shown in FIG. 7C-1.

Step S16: Perform the metal wiring process. In this step, metal deposition is performed. Metal vapor deposition and lift-off methods are used for patterning the Ni/Au metal layer and forming bonding pads for the gate, drain, and source electrodes as well as the interconnection metal 36, as shown in FIG. 7D-1 and FIG. 7D-2. Alternatively, in this step, the gate bonding pad region G connected electrically with the gate electrode can be formed concurrently, as the structures shown in FIG. 7G.

Step S17: Deposit and pattern passivation layer. As shown in FIG. 7E-1 and FIG. 7E-2, a passivation layer 40 is grown by PECVD. The material is selected from the group consisting of SiOₓ, SiOₓN_{y}, or SiNₓ. Finally, the passivation layer 40 is patterned for exposing the bonding pad region. For example, wet etching using BOE is adopted for exposing the drain and source bonding pad regions 42, 43 for subsequent wire bonding.

Because p-GaN is an inverted trapezoidal structure, a sloped capacitor will be formed in the field plate region 264 at the dashed circle in FIG. 7F-1 and FIG. 7F-2. This capacitor will induce the field plate effect having the main function of distributing the high-density electric field below the gate electrode. In addition to increasing the breakdown voltage Vds between the drain and the source of the HEMT, it also suppresses the electron trapping effect below the gate electrode and hence reducing current collapse during the operation of the HEMT.

Step S18: Fabricate the gate field-plate metal. The metal vapor deposition and metal left-off methods are adopted to form the gate field-plate metal 62 for the D-mode HEMT, as shown in the final structures in FIG. 7F-1 and FIG. 7F-2. The gate field-plate metal 62 is adjacent to the gate field-plate dielectric layer 92. The top view of the SEG p-GaN gate E-mode AlGaN/GaN HEMT using a D-mode AlGaN/GaN HEMT without gate dielectric layer as the gate protection device is shown in FIG. 7G.

Embodiment 2: An etched p-GaN gate E-mode AlGaN/GaN HEMT using a thin etched p-GaN gate D-mode AlGaN/GaN HEMT without gate dielectric layer as the gate protection device. This done by two etching process steps to create these two devices.

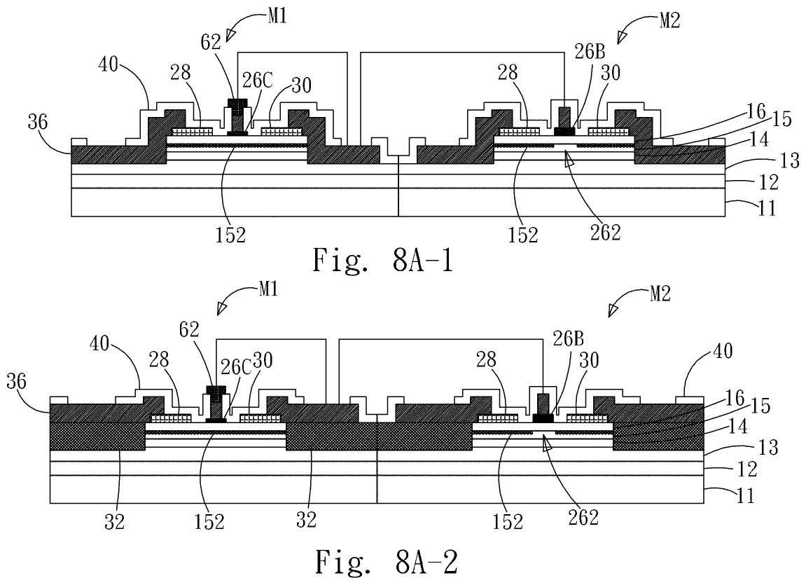

FIG. 8A-1 and FIG. 8A-2 are schematic diagrams after device fabrication using different device isolation processes. In FIG. 8A-2, a plurality of energy destructive ion implantations 32 are adopted. In general, heavy atoms such as boron or oxygen atoms are used for isolating devices. In FIG. 8A-1, dry etching to the highly resistive i-GaN buffer layer (C-doped) can be adopted for isolating devices.

As shown in FIG. 8A-1 and FIG. 8A-2, the etched p-GaN gate E-mode AlGaN/GaN HEMT using a thin etched p-GaN gate D-mode AlGaN/GaN HEMT without gate dielectric layer as the gate protection device according to the present invention comprises the epitaxial structure 34 and is divided into a left region and a right region. In the left region, a thin etched p-GaN gate D-mode AlGaN/GaN HEMT without gate dielectric layer M1 is formed. In the right region, an etched p-GaN gate E-mode AlGaN/GaN HEMT M2 is formed. This etched p-GaN gate E-mode AlGaN/GaN HEMT M2 includes an etched p-GaN gate structure 26B. In addition, although the 2DEG is formed at the junction i-AlₓGaN/i-GaN of the i-GaN channel layer 15, due to the existence of the etched p-GaN gate structure 26B, the 2DEG 152 below the etched p-GaN gate structure 26B in the i-GaN channel layer 15 will be depleted, giving a depletion region 262 without 2DEG 152.

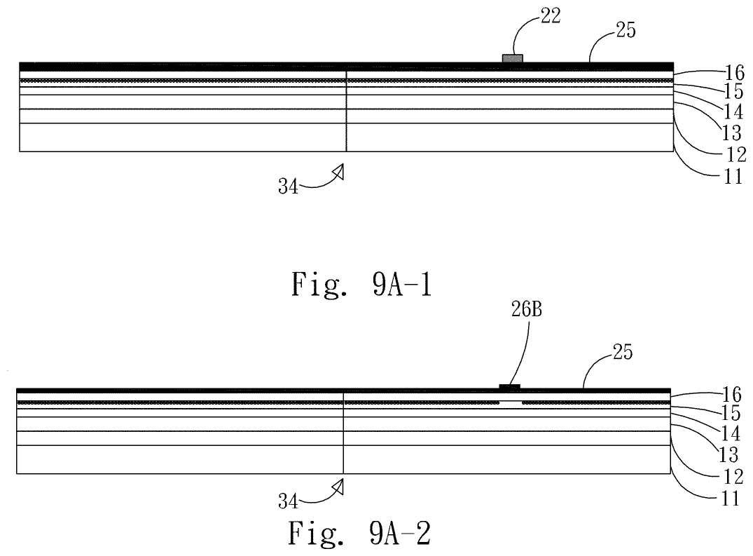

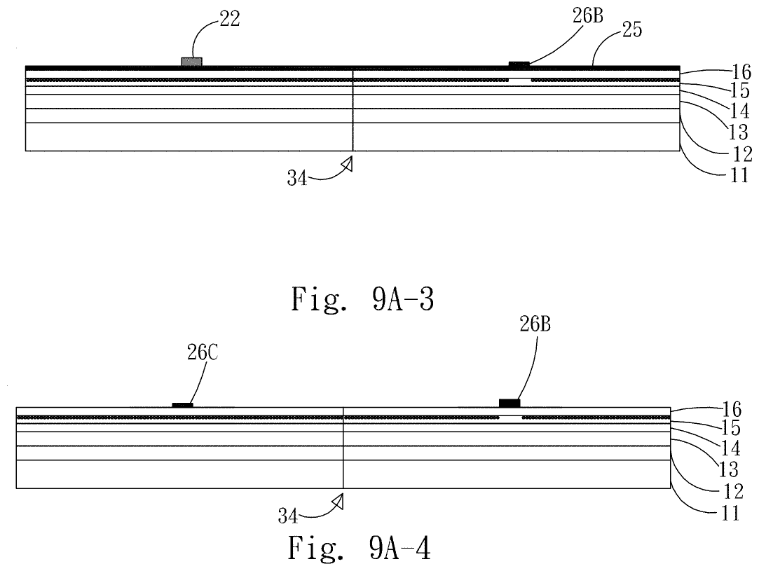

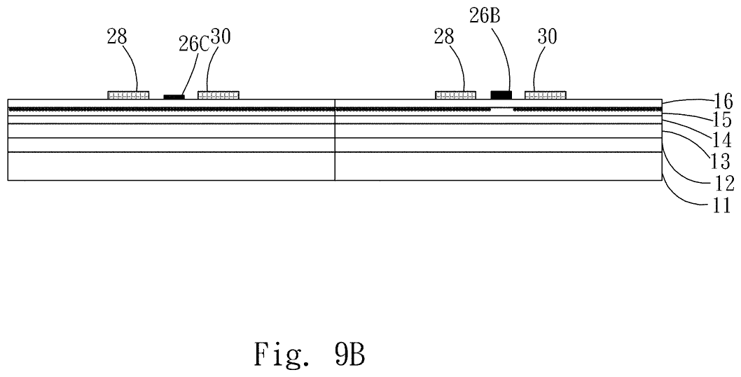

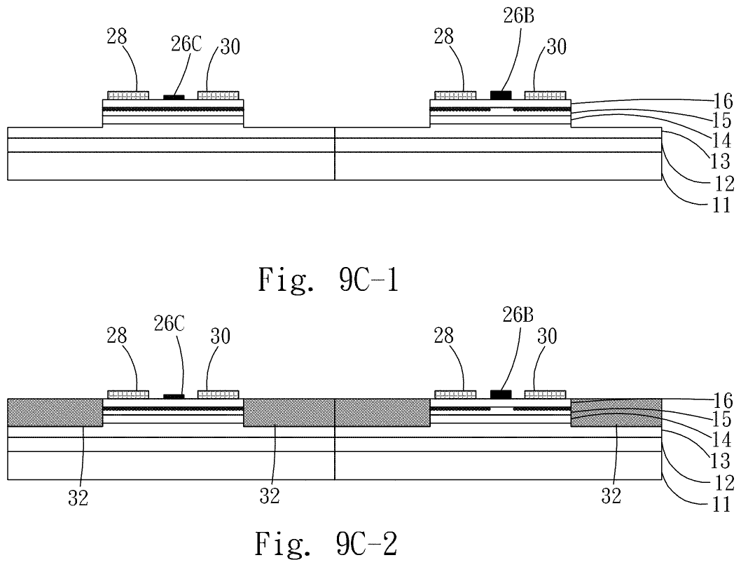

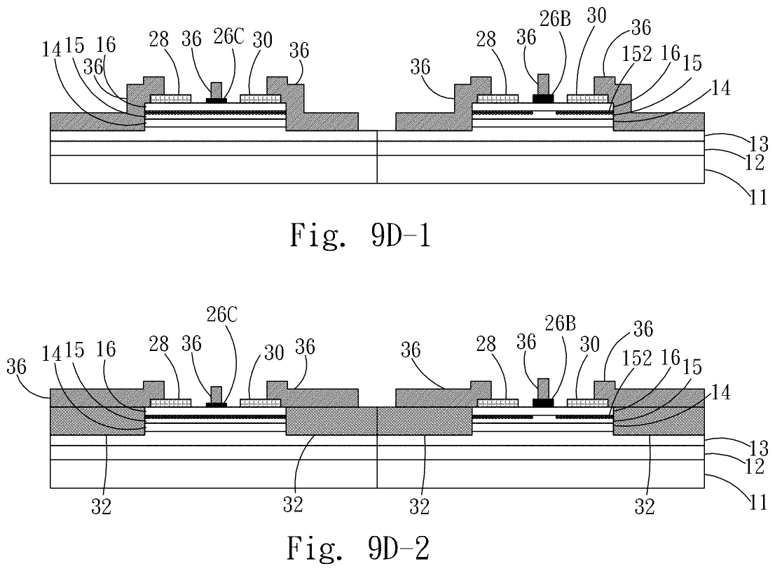

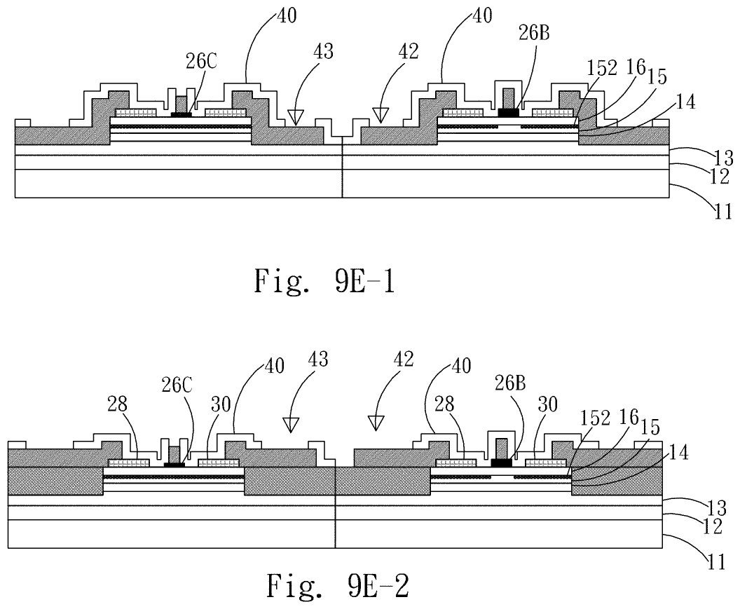

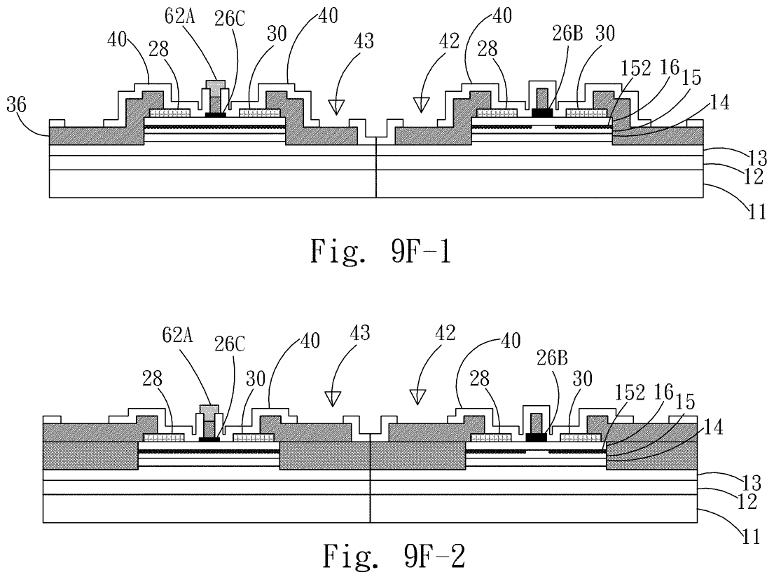

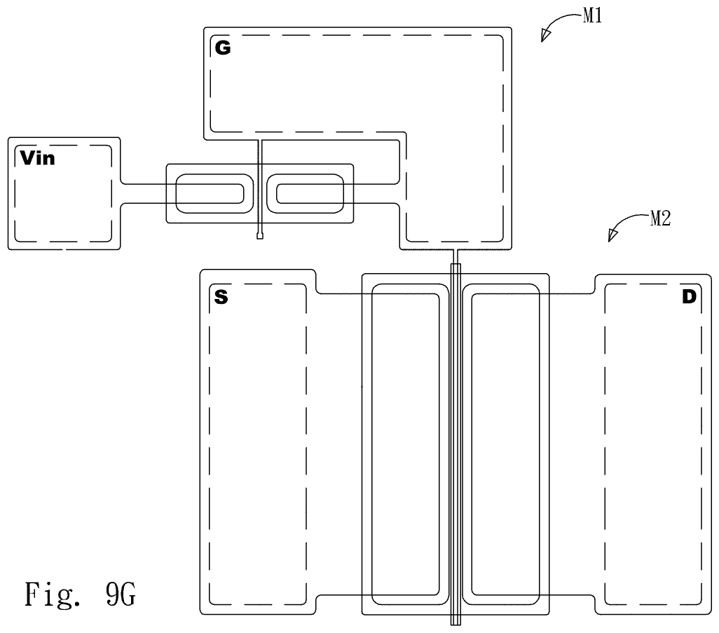

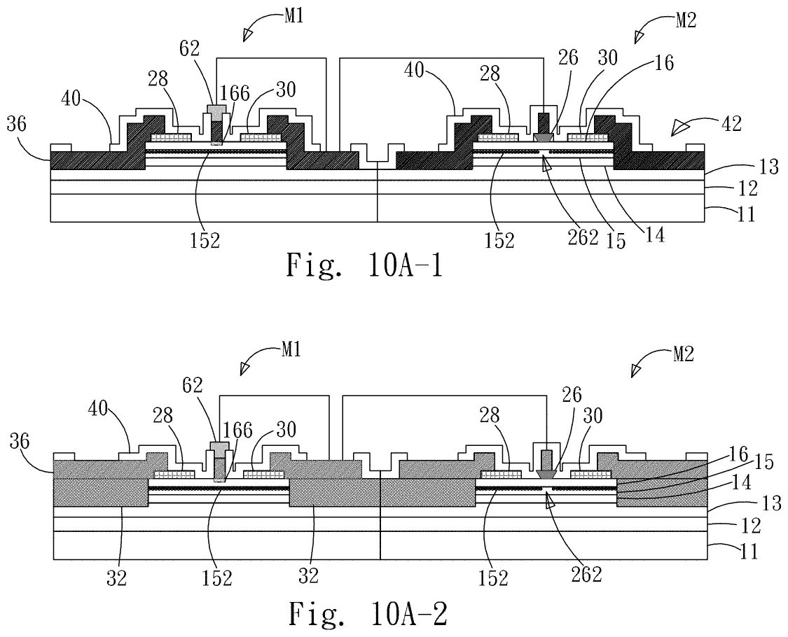

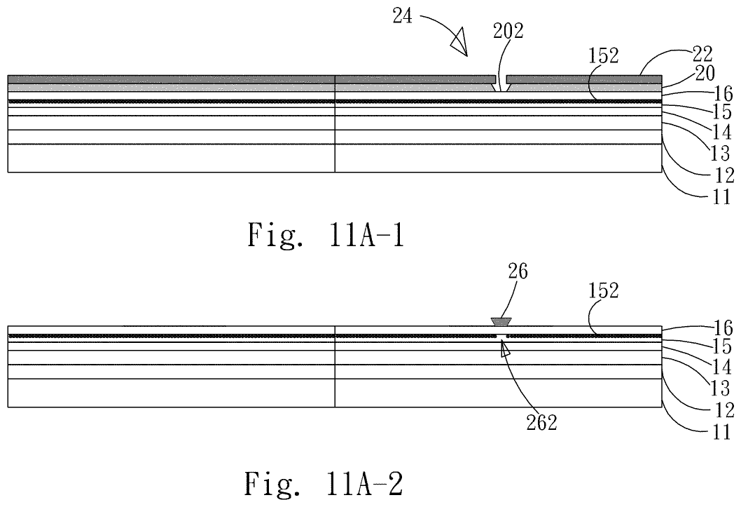

Step S21: Fabricate the etched p-GaN gate of the E-mode AlGaN/GaN HEMT. First, as shown in FIG. 9A-1˜9A-4, a p-GaN layer is grown on the Ga-face AlGaN/GaN epitaxial structure according to the present invention using MOCVD. Next, define the p-GaN gate of the E-mode AlGaN/GaN HEMT region by using photoresist 22 and exposure method. Dry etching is adopted to etch partially depth of the p-GaN outside the region to the AlGaN blocking layer of the Ga-face AlGaN/GaN epitaxial structure leaving a thin p-GaN unetched layer in the rest of the region according to the present invention. Then, the photoresist 22 is stripped using stripper. As shown in FIG. 9A-2 and FIG. 9A-4, next, define the thin p-GaN gate of the D-mode AlGaN/GaN HEMT region by using photoresist 22 and exposure method. Finally, dry etching is adopted to etch the rest of the thin p-GaN to the AlGaN layer, this will etched away a little bit of the p-GaN gate of the E-mode AlGaN/GaN HEMT, but it won't affect the performance of the p-GaN gate of the E-mode AlGaN/GaN HEMT. Thereby, the etched p-GaN gate is fabricated.

According to Embodiment 2, since the process steps as shown in FIG. 9B to FIG. 9F-1 are identical to those according to Embodiment 1 as shown in FIG. 7B to FIG. 7F-2, the details will not be repeated. The top view of the etched p-GaN gate E-mode AlGaN/GaN HEMT using a D-mode AlGaN/GaN HEMT without gate dielectric layer as the gate protection device is shown in FIG. 9G.

Embodiment 3: An SEG p-GaN gate—E-mode AlGaN/GaN HEMT using a fluorine lightly implanted D-mode AlGaN/GaN HEMT without gate dielectric layer as the gate protection device.

As shown in FIG. 10A-1 and FIG. 10A-2, the characteristics of the SEG p-GaN gate E-mode AlGaN/GaN HEMT M2 using a fluorine lightly implanted D-mode AlGaN/GaN HEMT M1 without gate dielectric layer as the gate protection device according to the present invention include the epitaxial structure 34 of AlGaN/GaN designed according to the present invention and a p-GaN inverted trapezoidal gate structure 26 located on a first i-AlxGaN layer 16. Although the 2DEG is formed at the junction i-AlxGaN/i-GaN of the i-GaN channel layer 15, due to the existence of the p-GaN inverted trapezoidal gate structure 26, the 2DEG below the p-GaN inverted trapezoidal gate structure 26 in the i-GaN channel layer 15 will be depleted. FIG. 10A-1 and FIG. 10A-2 are schematic diagrams after device fabrication using different device isolation processes. In FIG. 10A-2, a plurality of energy destructive ion implantations 32 are adopted. In general, heavy atoms such as boron or oxygen atoms are used for isolating devices. In FIG. 10A-1, dry etching to the highly resistive i-GaN buffer layer (C-doped) can be adopted for isolating devices.

The SEG p-GaN gate E-mode AlGaN/GaN HEMT M2 using a fluorine lightly implanted D-mode AlGaN/GaN HEMT M1 without gate dielectric layer as the gate protection device according to the present invention comprises the epitaxial structure 34 of AlGaN/GaN designed according to the present invention and is divided into a left region and a right region. In the left region, a fluorine lightly implanted D-mode AlGaN/GaN HEMT M1 without gate dielectric layer is formed. In the right region, an SEG p-GaN gate E-mode AlGaN/GaN HEMT M2 is formed. This SEG p-GaN gate E-mode AlGaN/GaN HEMT M2 includes a p-GaN inverted trapezoidal gate structure 26. In addition, although the 2DEG is formed at the junction i-AlxGaN/i-GaN of the i-GaN channel layer 15, due to the existence of the p-GaN inverted trapezoidal gate structure 26, the 2DEG below the p-GaN inverted trapezoidal gate structure 26 in the i-GaN channel layer 15 will be depleted, giving a depletion region 262 without 2DEG.

In the following, the fabrication method for the present embodiment will be described. Nonetheless, a person having ordinary skill in the art should know that the present embodiment and its metal layout is not limited to the fabrication method.

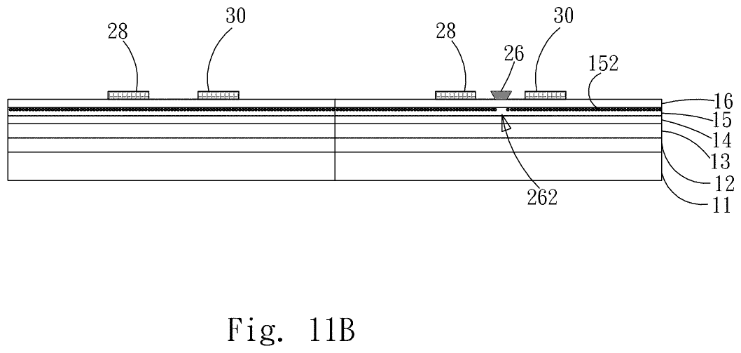

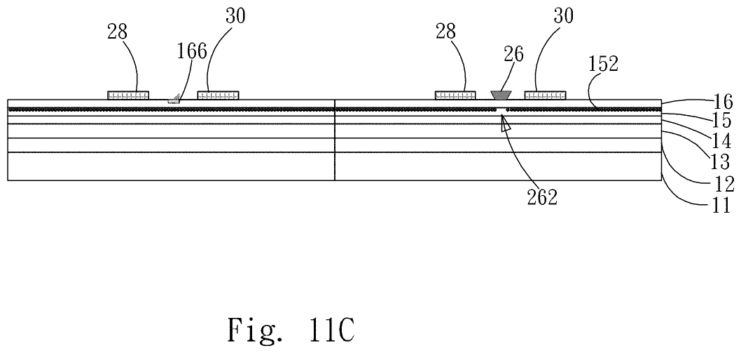

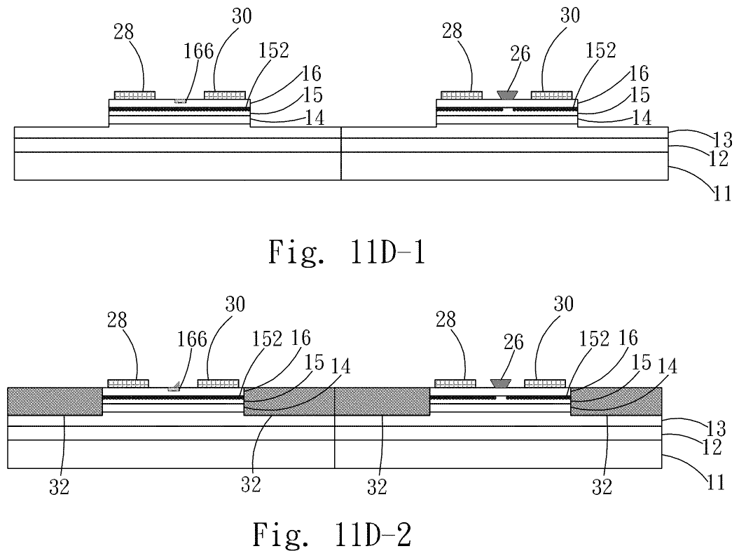

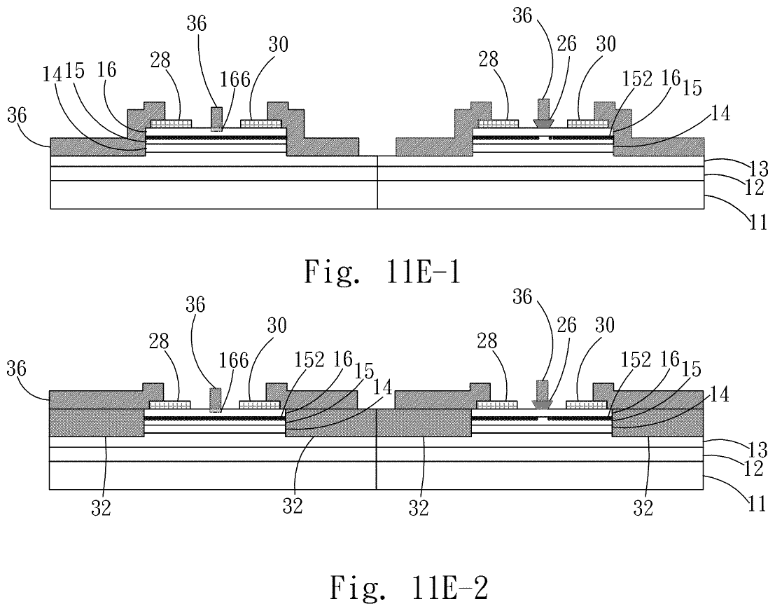

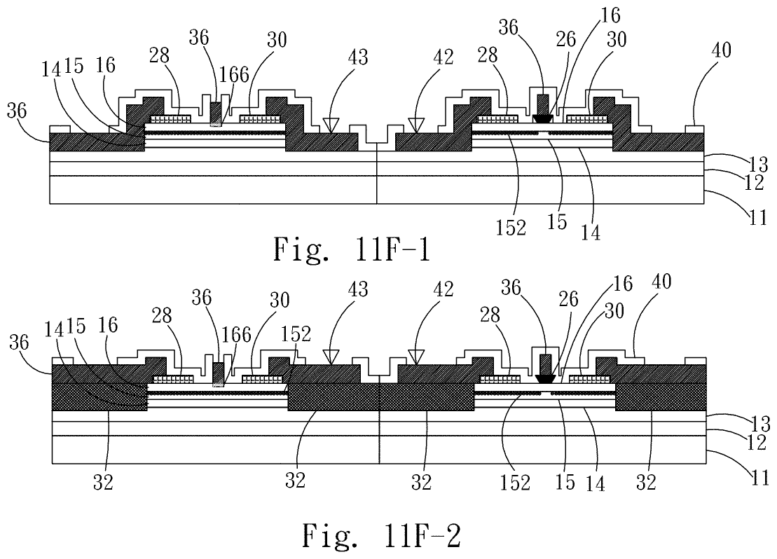

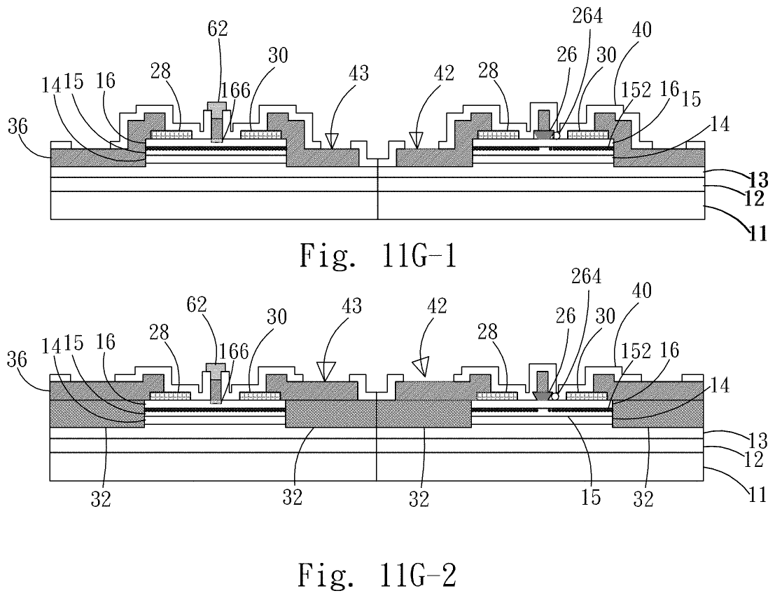

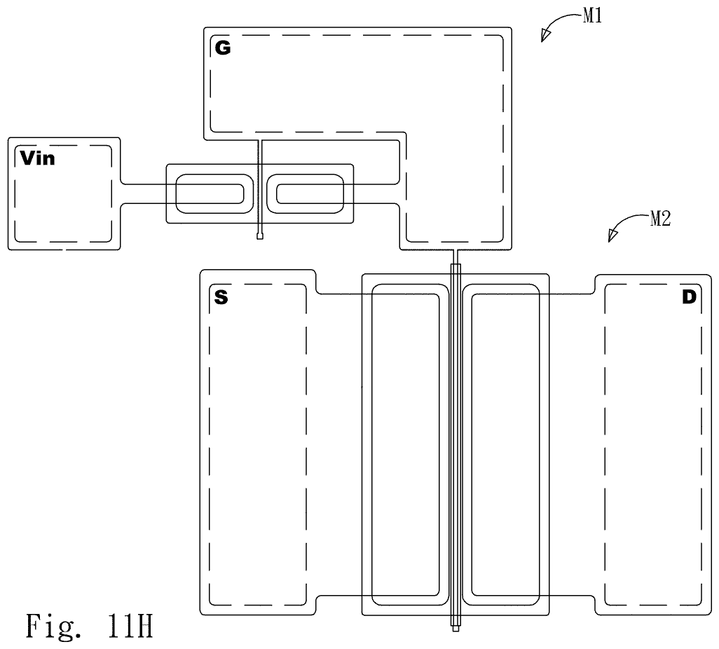

Step S31: Pattern the silicon dioxide mask layer 20. First, as shown in FIG. 11A-1, deposit a silicon dioxide mask layer 20 on the epitaxial structure of Ga-face AlGaN/GaN according to the present invention using plasma-enhanced chemical vapor deposition (PECVD) with a thickness of around 100-200 nm. Next, define the gate SEG region 24 by using photoresist and exposure method. Finally, the silicon dioxide mask layer 20 in the region 24 is etched by a wet etching method using buffered oxide etchant (BOE) to expose the surface of the epitaxy. Then, the photoresist 22 is stripped using stripper. Because the wet etching is isotropic, in addition to etching downward, lateral etching will occur concurrently. Thereby, the opening of the silicon dioxide mask layer 20 in the region 24 will form an inverted trapezoidal structure.

Step S32: Form the p-GaN inverted trapezoidal gate structure 26 using SEG. First, p-GaN SEG is performed using metal-organic chemical vapor deposition (MOCVD) and only the exposed surface of the epitaxy can grow p-GaN. Because the growth of p-GaN in MOCVD is also isotropic, in addition to growing upward, lateral growth will occur concurrently and thus forming an inverted trapezoidal structure of p-GaN, which is just the p-GaN inverted trapezoidal gate structure 26. Finally, the silicon dioxide mask layer 20 is etched by a wet etching method using BOE and forming the structure shown in FIG. 11A-2.

Then, because the p-GaN SEG region 24 occupies only a small portion of the whole epitaxy wafer, the loading effect will occur easily. Namely, the growth rate on the defined region for p-GaN is three to four times the growth rate on the general surface. Thereby, the p-type doping concentration in p-GaN will be equal to 1/3 to 1/4 of the expected.

Step S33: Form the drain ohmic contact 30 and the source ohmic contact 28. A metal layer, for example, a general Ti/Al/Ti/Au or Ti/Al/Ni/Au metal layer, is deposited on the epitaxy wafer using metal vapor deposition. Then a metal lift-off method is adopted to pattern the deposited metal layer for forming the drain and source electrodes on the epitaxy wafer. Afterwards, a thermal treatment is performed at 700˜900° C. for 30 seconds to make the drain and source electrodes become ohmic contacts 30, 28, as shown in FIG. 11B.

Step S34: Define the fluorine lightly implanted region 27 of D-mode AlGaN/GaN HEMT M1 without gate dielectric layer by using photoresist and exposure method. Next, a shallow and light dose fluorine is implanted into the defined region 27 by ICP or Ion Implanter to form a fluorine implantation 166 in i-AlₓGaN layer 16 of the D-mode AlGaN/GaN HEMT M1 without gate dielectric layer, after the implantation, the photoresist 22 is stripped using stripper as shown in FIG. 11C.

Step S35: Perform device isolation process. In this step, a plurality of energy destructive ion implantation 32 are adopted. In general, heavy atoms such as boron or oxygen atoms are used for isolating devices, as shown in FIG. 11D-2. Alternatively, dry etching to the highly resistive i-GaN buffer layer (C-doped) can be adopted for isolating devices, as shown in FIG. 11D-1.

Step S36: Perform the metal wiring process. In this step, metal deposition is performed. Metal vapor deposition and lift-off methods are used for patterning the Ni/Au metal layer and forming bonding pads for the gate, drain, and source electrodes as well as the interconnection metal 35, as shown in FIG. 11E-1 and FIG. 11E-2. Alternatively, in this step, the gate bonding pad region connected electrically with the gate electrode can be formed concurrently, as the structures shown in FIG. 11G.

Step S37: Deposit and pattern passivation layer. As shown in FIG. 11F-1 and FIG. 11F-2, a passivation layer 40 is grown by PECVD. The material is selected from the group consisting of SiOₓ, SiOₓN_{y}, or SiNₓ. Finally, the passivation layer 40 is patterned for exposing the bonding pad region. For example, wet etching using BOE is adopted for exposing the drain and source bonding pad regions 42, 43 for subsequent wire bonding.

Because p-GaN is an inverted trapezoidal structure, a sloped capacitor will be formed in the field plate region 264 at the dashed circle in FIG. 11F-1 and FIG. 11F-2. This capacitor will induce the field plate effect having the main function of distributing the high-density electric field below the gate electrode. In addition to increasing the breakdown voltage Vds between the drain and the source of the HEMT, it also suppresses the electron trapping effect below the gate electrode and hence reducing current collapse during the operation of the HEMT.

Step S38: Fabricate the gate field-plate metal. The metal vapor deposition and metal left-off methods are adopted to form the gate field-plate metal 62 for the D-mode HEMT, as shown in the final structures in FIG. 11G-1 and FIG. 11G-2. The gate field-plate metal 62 is adjacent to the gate field-plate dielectric layer 92, where the fluorine implantation 166 is located under the gate field-plate metal 62. The top view of the SEG p-GaN gate E-mode AlGaN/GaN HEMT using a D-mode AlGaN/GaN HEMT without gate dielectric layer as the gate protection device is shown in FIG. 11H.

Embodiment 4: An etched p-GaN gate—E-mode AlGaN/GaN HEMT using a fluorine lightly implanted D-mode AlGaN/GaN HEMT without gate dielectric layer as the gate protection device

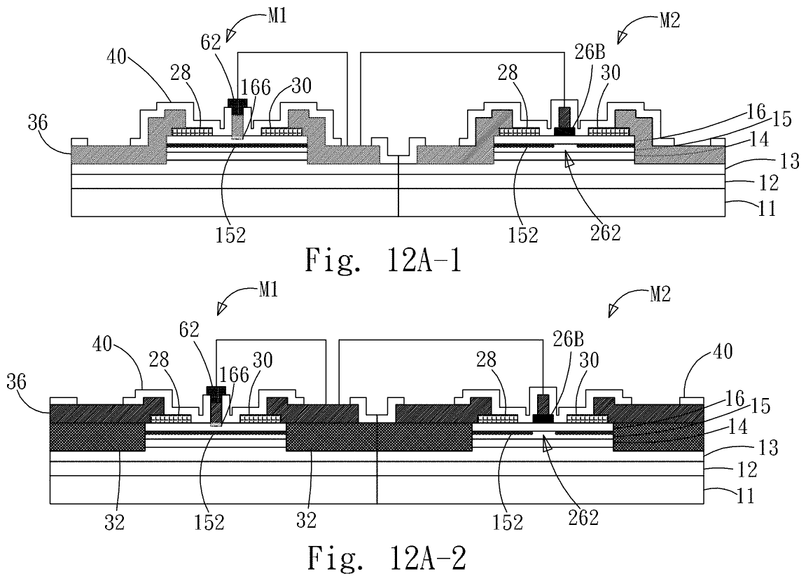

FIG. 12A-1 and FIG. 12A-2 are schematic diagrams after device fabrication using different device isolation processes. In FIG. 12A-2, multiple-energy destructive ion implantation is adopted. In general, heavy atoms such as boron or oxygen atoms are used for isolating devices. In FIG. 12A-1, dry etching to the highly resistive i-GaN buffer layer (C-doped) can be adopted for isolating devices.

As shown in FIG. 12A-1 and FIG. 12A-2, the etched p-GaN gate E-mode AlGaN/GaN HEMT using a fluorine lightly implanted D-mode AlGaN/GaN HEMT without gate dielectric layer as the gate protection device according to the present invention comprises the epitaxial structure and is divided into a left region and a right region. In the left region, a fluorine lightly implanted D-mode AlGaN/GaN HEMT M1 without gate dielectric layer is formed with the fluorine implantation 166. In the right region, an etched p-GaN gate E-mode AlGaN/GaN HEMT M2 is formed. This etched p-GaN gate E-mode AlGaN/GaN HEMT M2 includes an etched p-GaN gate structure 26B. In addition, although the 2DEG is formed at the junction i-AlₓGaN/i-GaN of the i-GaN channel layer 15, due to the existence of the etched p-GaN gate structure 26B, the 2DEG below the etched p-GaN gate structure 26B in the i-GaN channel layer 15 will be depleted, giving a depletion region 262 without 2DEG.

Step S41: Fabricate the etched p-GaN gate. First, as shown in FIG. 13A-1 and FIG. 13A-2, a p-GaN layer is grown on the Ga-face AlGaN/GaN epitaxial structure according to the present invention using MOCVD. Next, define the p-GaN gate region by using photoresist 22 and exposure method. Finally, dry etching is adopted to etch the p-GaN outside the region to the AlGaN blocking layer of the Ga-face AlGaN/GaN epitaxial structure according to the present invention. Then, the photoresist 22 is stripped using stripper. Thereby, the etched p-GaN gate is fabricated.

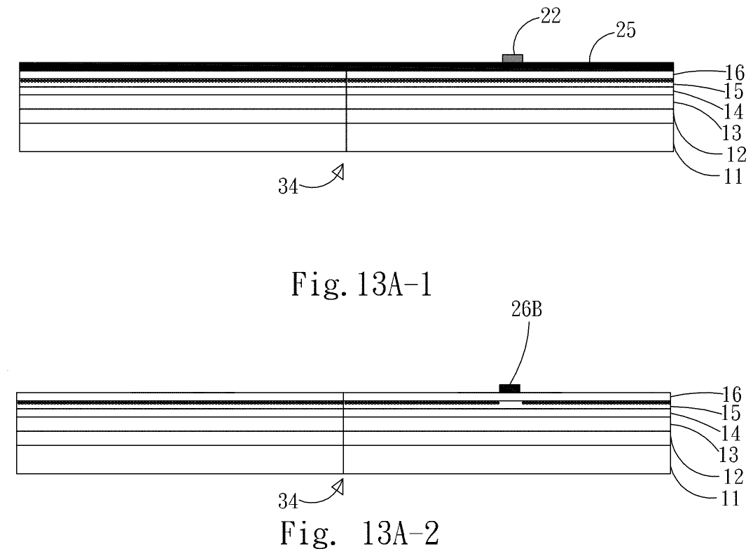

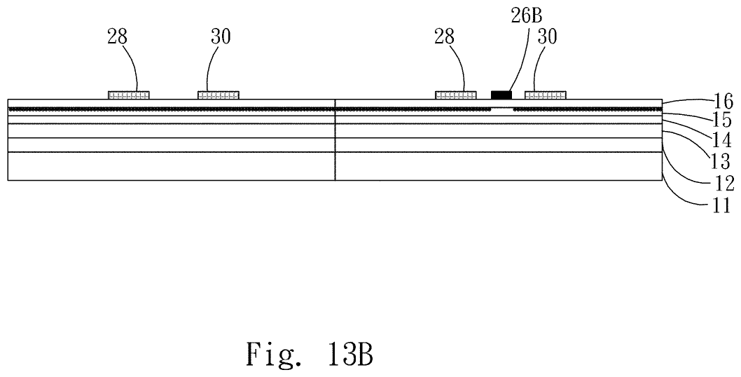

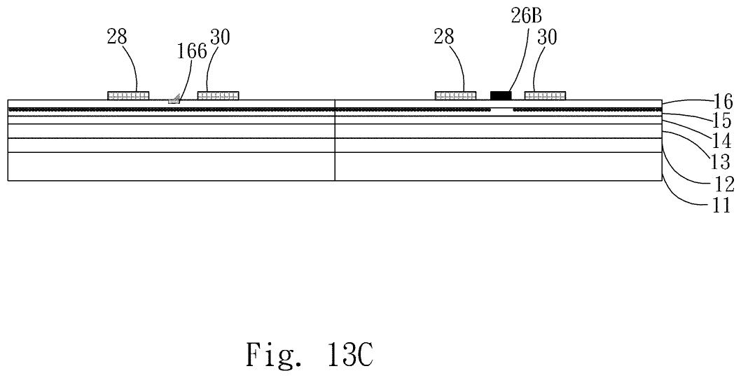

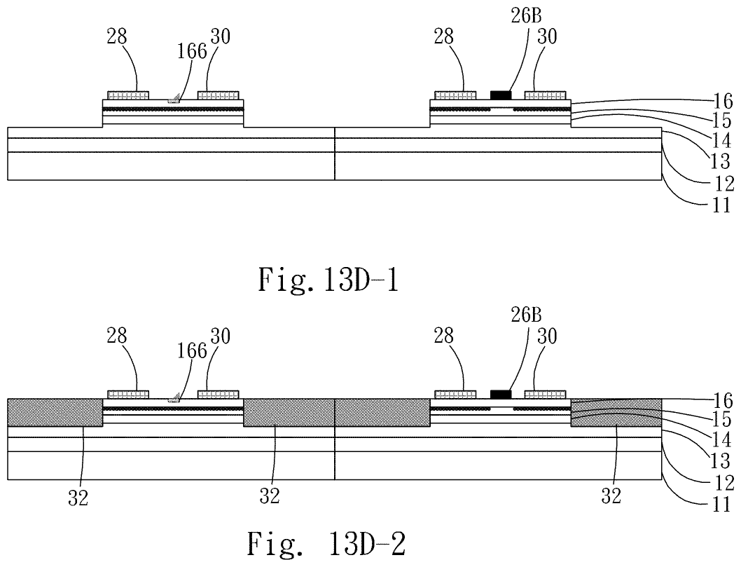

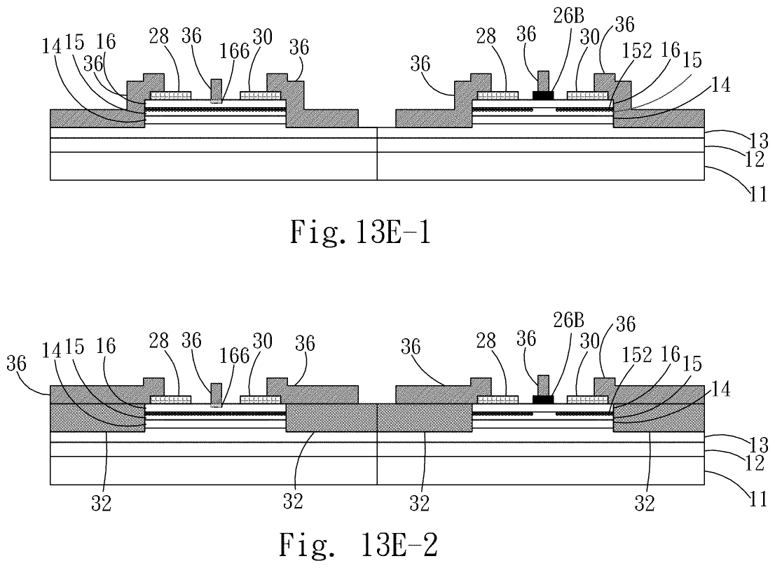

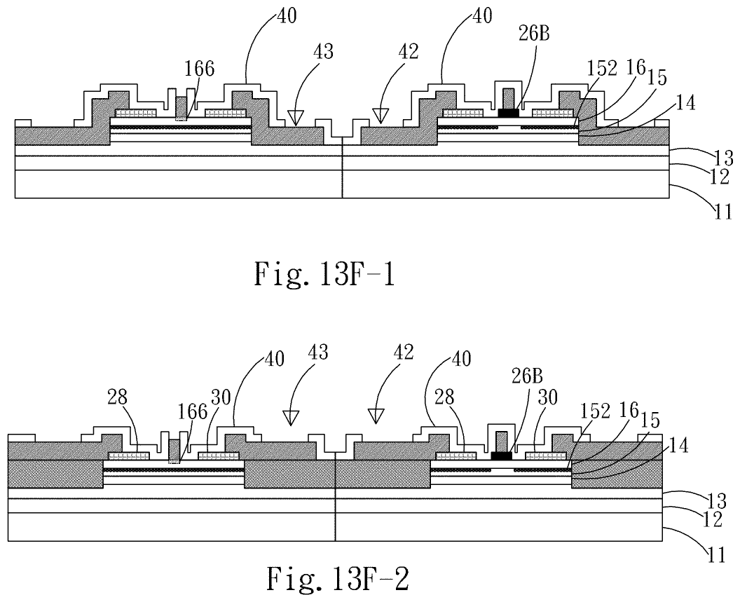

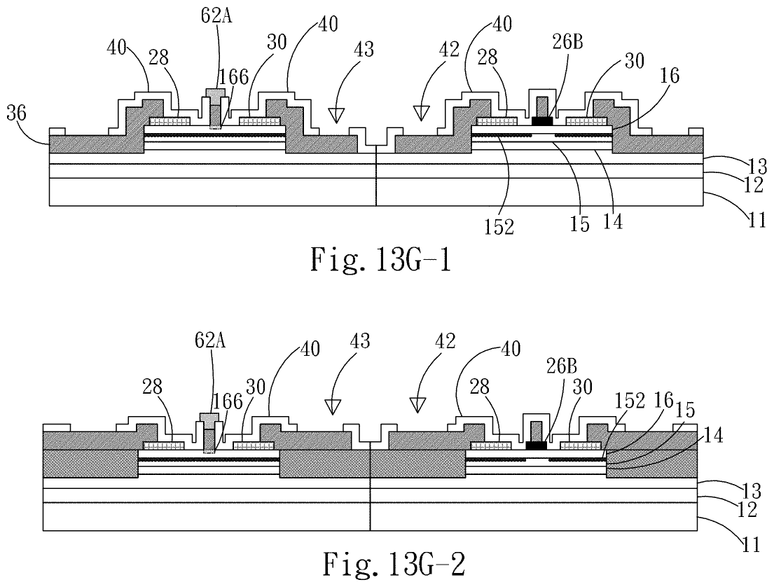

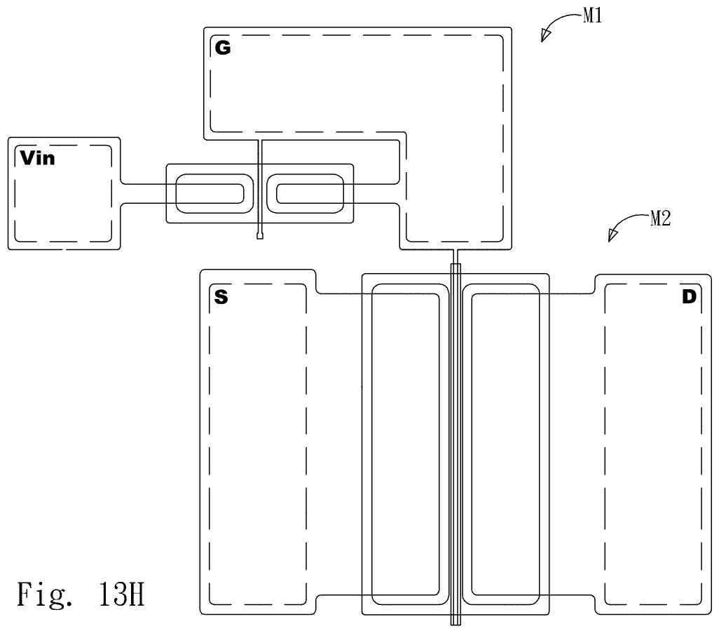

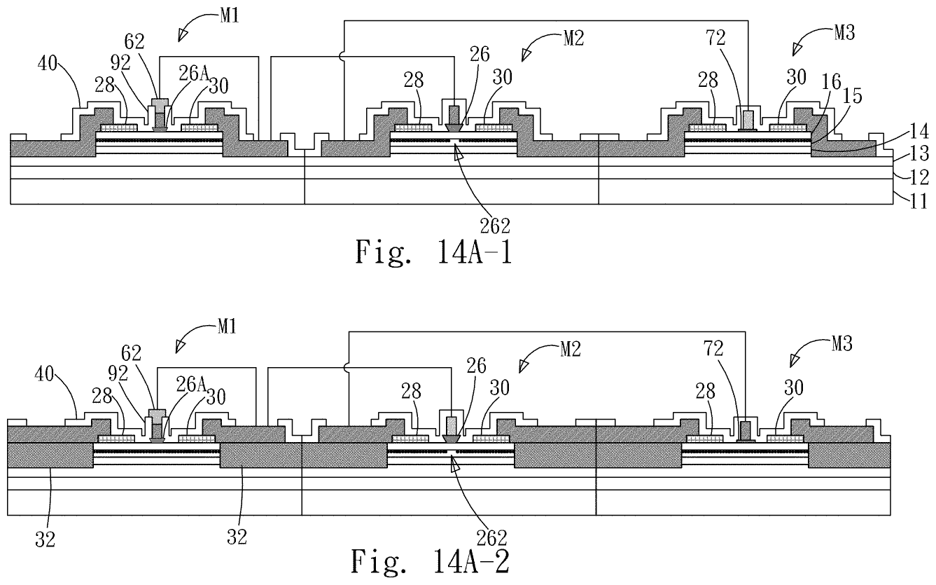

According to Embodiment 4, since the process steps as shown in FIG. 13B to FIG. 13G-1 and FIG. 13G-2 are identical to those according to Embodiment 3 as shown in FIG. 13B to FIG. 13G-1 and FIG. 13G-2, the details will not be repeated. The top view of the etched p-GaN gate E-mode AlGaN/GaN HEMT using a D-mode AlGaN/GaN HEMT without gate dielectric layer as the gate protection device is shown in FIG. 13H. Embodiment 1 to 4 can be expressed in the schematic diagram as shown in FIG. 4F.

Embodiment 5: As shown in FIG. 14A-1 and FIG. 14A-2, a hybrid E-mode AlGaN/GaN HEMT formed by the SEG p-GaN gate E-mode AlGaN/GaN HEMT using a thin SEG p-GaN gate D-mode AlGaN/GaN HEMT without gate dielectric layer as the gate protection device cascoding to a D-mode AlGaN/GaN HEMT with gate dielectric layer to increase the off-state breakdown voltage of the hybrid E-mode AlGaN/GaN HEMT.

As shown in FIG. 14A-1 and FIG. 14A-2, the hybrid E-mode AlGaN/GaN HEMT according to Embodiment 5 comprises the epitaxial structure of AlGaN/GaN designed according to the present invention and is divided into a left region, a middle region, and a right region. In the left region, a thin SEG p-GaN gate D-mode AlGaN/GaN HEMT without gate dielectric layer M1 is formed. In the middle region, an SEG p-GaN gate E-mode AlGaN/GaN HEMT M2 is formed. This SEG p-GaN gate E-mode AlGaN/GaN HEMT M2 includes a p-GaN inverted trapezoidal gate structure 26. In addition, although the 2DEG is formed at the junction i-AlₓGaN/i-GaN of the i-GaN channel layer 15, due to the existence of the p-GaN inverted trapezoidal gate structure 26, the 2DEG below the p-GaN inverted trapezoidal gate structure 26 in the i-GaN channel layer 15 will be depleted, giving a depletion region 262 without 2DEG. In the right region, a D-mode AlGaN/GaN HEMT with gate dielectric layer M3 is formed. Next, similar as described in the previous fabrication method of FIG. 7A-1 and FIG. 7A-4 to FIG. 7C-1 to form
1. a p-GaN inverted trapezoidal structure 26A on the left thin SEG p-GaN gate D-mode AlGaN/GaN HEMT M1 without gate dielectric layer and the middle region, SEG p-GaN gate E-mode AlGaN/GaN HEMT M2.
2. The drain and source electrodes ohmic contacts on M1, M2 and M3.
3. M1, M2 and M3 device isolation process.

Step S54: The gate dielectric layer 72 is formed for the D-mode AlGaN/GaN HEMT with gate dielectric layer M3 in the right region is fabricated. A dielectric layer is deposited by PECVD. The material is selected form the group consisting of SiOx, SiOxNy, or SiNx; the thickness is 10 to 100 nm. Then, define the region of the gate dielectric layer 72 for the D-mode AlGaN/GaN HEMT by using photoresist and exposure method. Finally, the dielectric layer outside the region is etched by a wet etching method using BOE; the dielectric layer in the region of the gate dielectric layer 72 is reserved. Afterwards, the photoresist is stripped using stripper and forming the structure shown in FIG. 15A-1 and FIG. 15A-2.

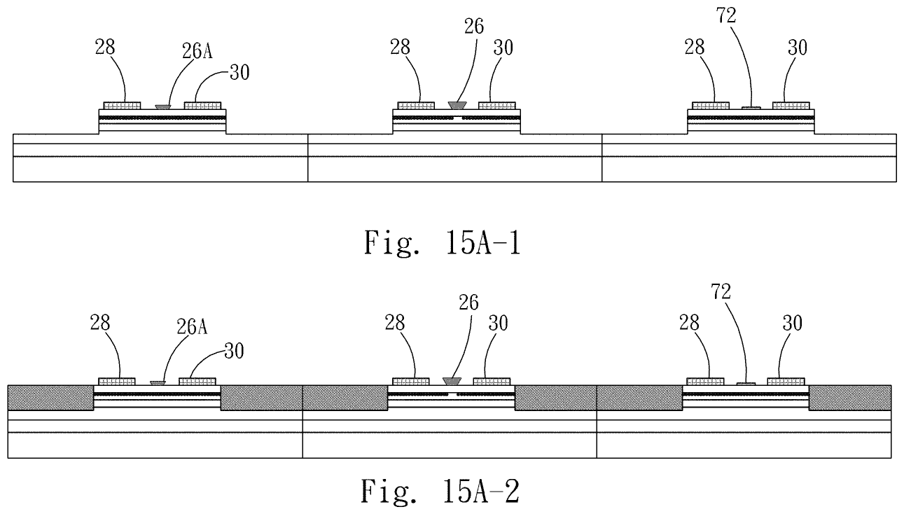

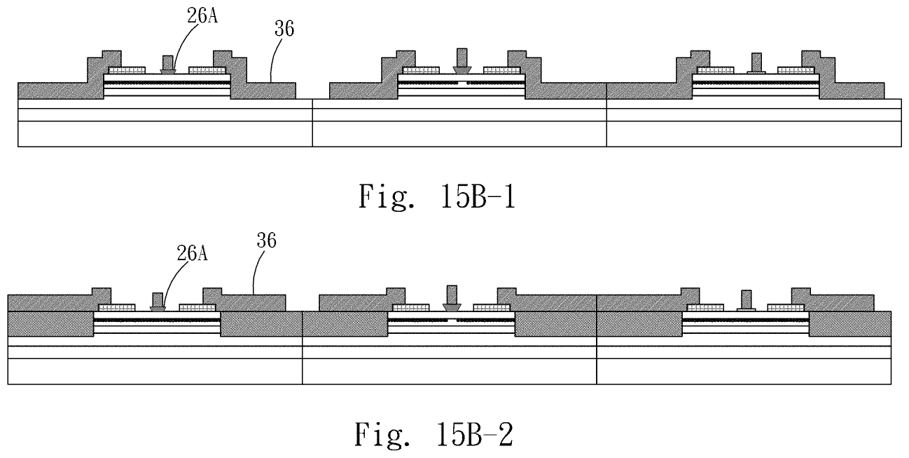

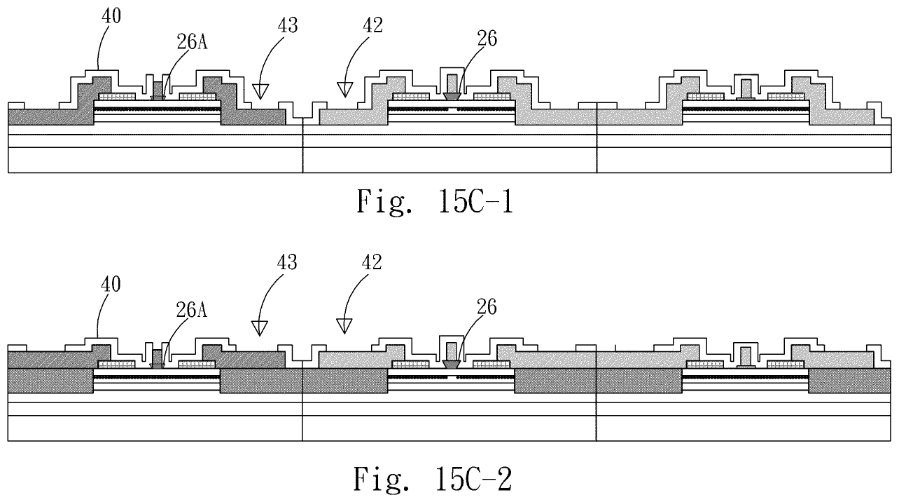

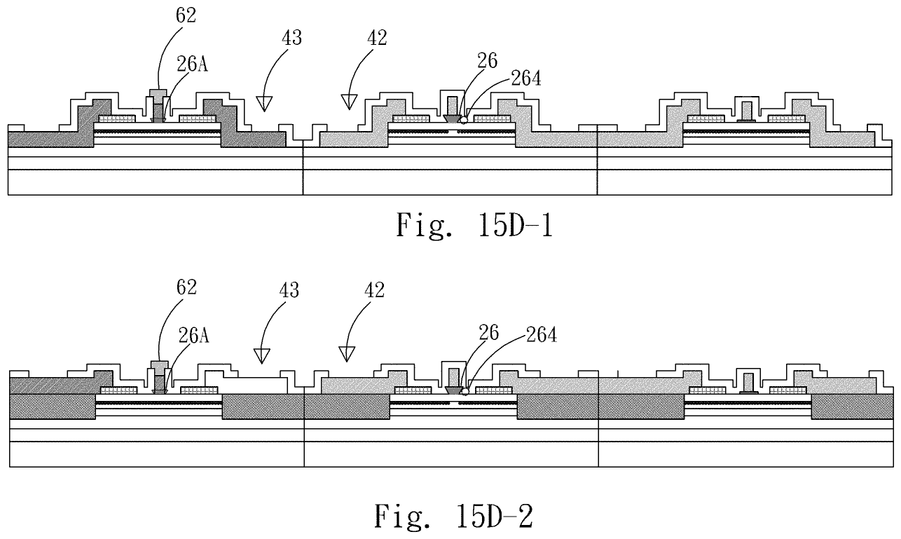

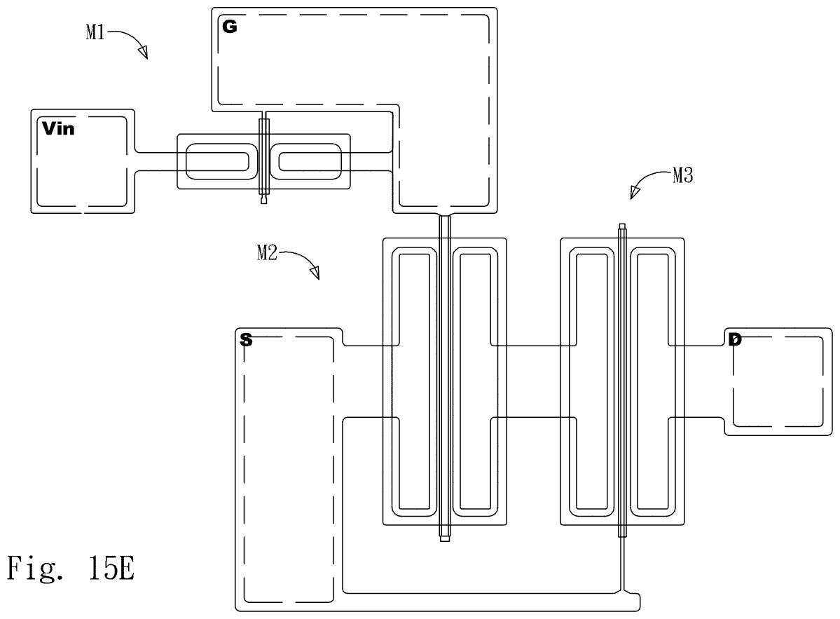

Step S55: Use metal vapor deposition (normally Ni/Au) and metal lift-off methods to form the gate electrode, the bonding pad regions for the drain and source electrodes, and the interconnection metal layer 36, as the structures shown in FIG. 15B. In addition, in this step, the metal wiring required for device operations can be formed concurrently. For example, the gate bonding pad region connected electrically with the gate electrode can be formed concurrently. Nonetheless, the present invention is not limited to the top views of the present invention.

Step S56: A passivation layer 40 is grown by PECVD. The material is selected form the group consisting of SiOx, SiOxNy, or SiNx. Finally, the passivation layer 40 is patterned for etching and exposing the bonding pad region and the region above the gate metal of the D-mode AlGaN/GaN HEMT without gate dielectric layer in the left region, and thus forming the structure shown in FIG. 15C.

Step S57: Finally, the metal vapor deposition and metal left-off methods are adopted to form the gate field-plate metal 62 of the D-mode AlGaN/GaN HEMT without gate dielectric layer M1 in the left region, as shown in the final structure in FIG. 15D. The field-plate metal 62 is adjacent to the gate field-plate dielectric layer 92.

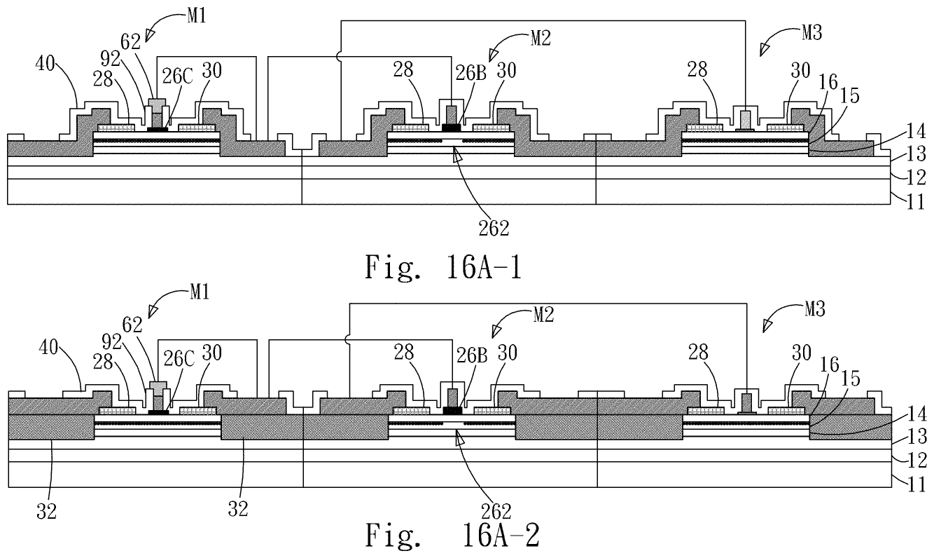

Embodiment 6: As shown in FIG. 16A-1 and FIG. 16A-2, a hybrid E-mode AlGaN/GaN HEMT formed by the etched p-GaN gate E-mode AlGaN/GaN HEMT using an etched p-GaN thin gate D-mode AlGaN/GaN HEMT without gate dielectric layer as the gate protection device cascoding to a D-mode AlGaN/GaN HEMT with gate dielectric layer to increase the off-state breakdown voltage of the hybrid E-mode AlGaN/GaN HEMT.

As shown in FIG. 16A-1 and FIG. 16A-2, the hybrid E-mode AlGaN/GaN HEMT according to Embodiment 6 comprises the epitaxial structure of AlGaN/GaN designed according to the present invention and is divided into a left region, a middle region, and a right region. In the left region, an etched p-GaN thin gate D-mode AlGaN/GaN HEMT without gate dielectric layer M1 is formed. In the middle region, an etched p-GaN gate E-mode AlGaN/GaN HEMT M2 is formed. This etched p-GaN gate E-mode AlGaN/GaN HEMT M2 includes an etched p-GaN gate structure. In addition, although the 2DEG is formed at the junction i-AlₓGaN/i-GaN of the i-GaN channel layer 15, due to the existence of the etched p-GaN gate structure, the 2DEG below the etched p-GaN gate structure in the i-GaN channel layer 15 will be depleted. In the right region, a D-mode AlGaN/GaN HEMT with gate dielectric layer M3 is formed.

The first process steps of Embodiment 6 are identical to those shown in FIG. 9A-1 to FIG. 9-A4 and M1, M2 and M3 device isolation process identical to Embodiment 5 for Embodiment 6. Hence, the details will not be repeated.

Step S64: The gate dielectric layer 72 for the D-mode AlGaN/GaN HEMT with gate dielectric layer in the right region is fabricated. A dielectric layer is deposited by PECVD. The material is selected form the group consisting of SiOₓ, SiOₓN_{y}, or SiNₓ; the thickness is 10 to 100 nm. Then, define the region of the gate dielectric layer 72 for the D-mode AlGaN/GaN HEMT by using photoresist and exposure method. Finally, the dielectric layer outside the region is etched by a wet etching method using BOE; the dielectric layer in the region of the gate dielectric layer 72 is reserved. Afterwards, the photoresist is stripped using stripper and forming the structure shown in FIG. 17A-1 and FIG. 17A-2.

Step S65: Use metal vapor deposition (normally Ni/Au) and metal lift-off methods to form the gate electrode, the bonding pad regions for the drain and source electrodes, and the interconnection metal layer 36, as the structures shown in FIG. 17B-1 and FIG. 17B-2. In addition, in this step, the metal wiring required for device operations can be formed concurrently. For example, the gate bonding pad region connected electrically with the gate electrode can be formed concurrently. Nonetheless, the present invention is not limited to the top views of the present invention.

Step S66: A passivation layer 40 is grown by PECVD. The material is selected form the group consisting of SiOₓ, SiOₓN_{y}, or SiNₓ. Finally, the passivation layer 40 is patterned for etching and exposing the bonding pad region and the region above the gate metal of the D-mode AlGaN/GaN HEMT without gate dielectric layer in the left region, and thus forming the structure shown in FIG. 17C-1 and FIG. 17C-2.

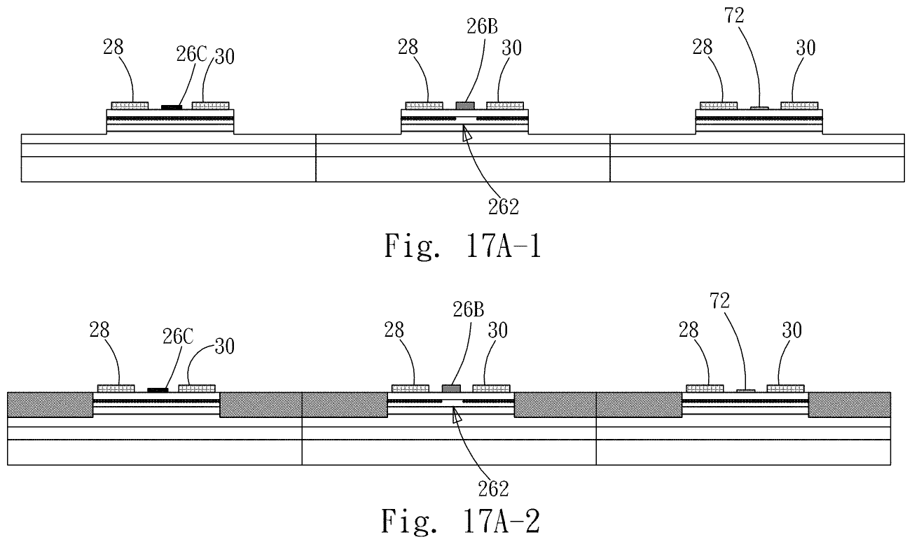

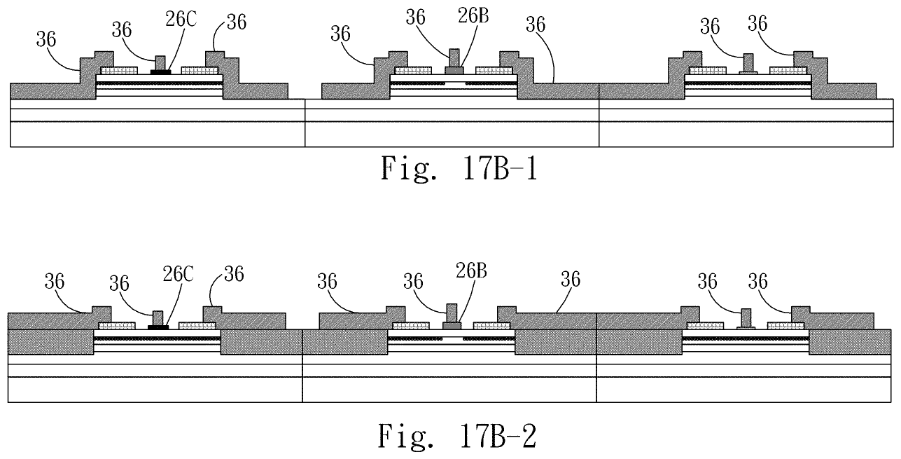

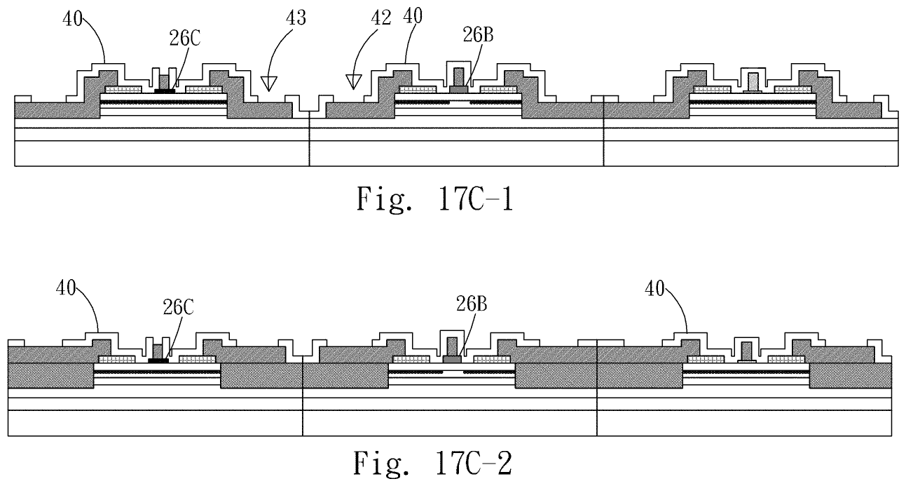

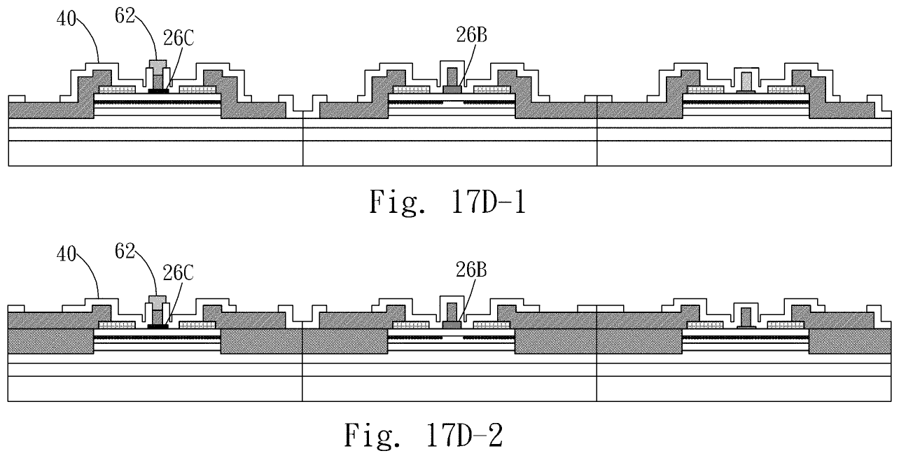

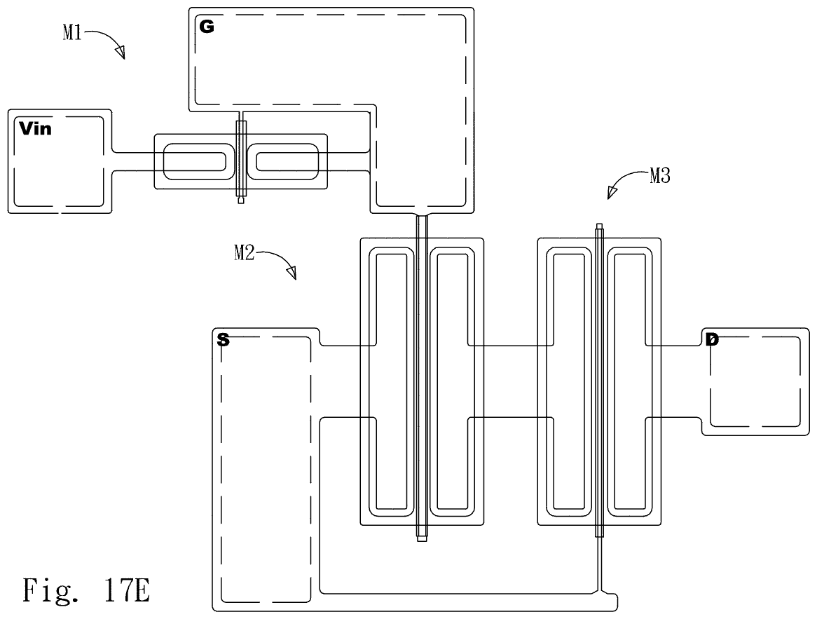

S67: Finally, the metal vapor deposition and metal left-off methods are adopted to form the gate field-plate metal 62 of the D-mode AlGaN/GaN HEMT without gate dielectric layer M1 in the left region, as shown in the final structure in FIG. 17D-1 and FIG. 17D-2. The field-plate metal 62 is adjacent to the gate field-plate dielectric layer 92. Top view of M1, M2 and M3 in this embodiment is shown in FIG. 17E.

Embodiment 7: As shown in FIG. 18A-1 and FIG. 18A-2, a hybrid E-mode AlGaN/GaN HEMT formed by the SEG p-GaN gate gate metal E-mode AlGaN/GaN HEMT using a Fluorine lightly implanted D-mode AlGaN/GaN HEMT without gate dielectric layer as the gate protection device cascoding to a D-mode AlGaN/GaN HEMT with gate dielectric layer to increase the off-state breakdown voltage of the hybrid E-mode AlGaN/GaN HEMT.

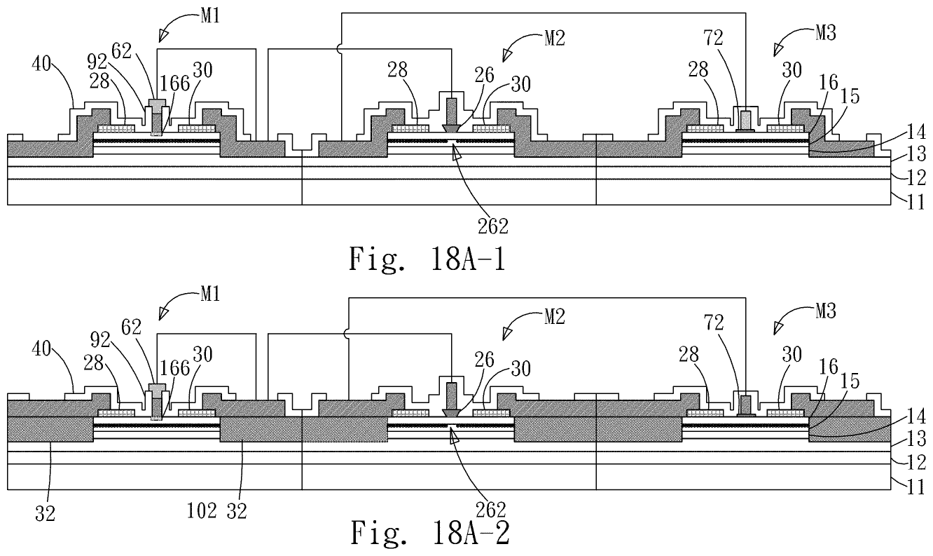

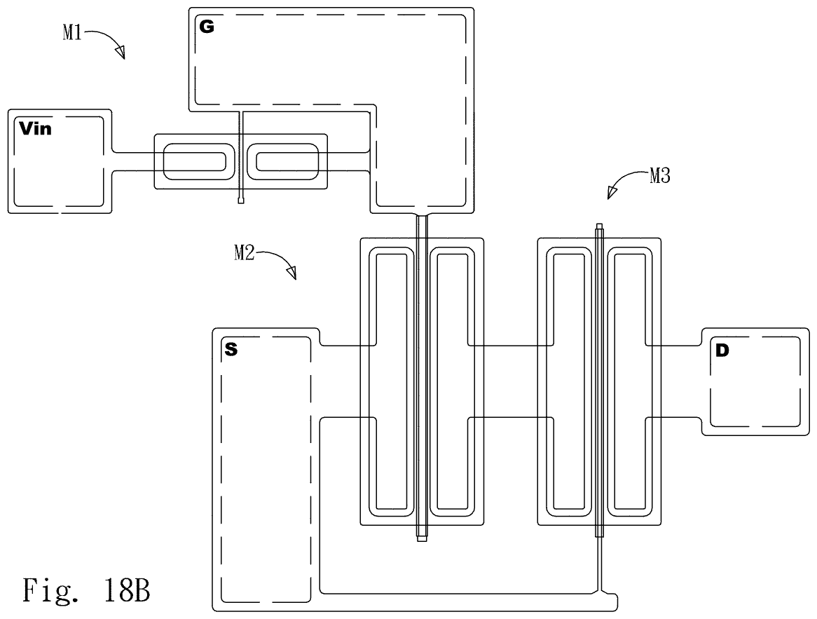

As shown in FIG. 18A-1 and FIG. 18A-2, the hybrid E-mode AlGaN/GaN HEMT according to Embodiment 7 comprises the epitaxial structure of AlGaN/GaN designed according to the present invention and is divided into a left region, a middle region, and a right region. In the left region, a fluorine lightly implanted D-mode AlGaN/GaN HEMT M1 without gate dielectric layer is formed with the fluorine implantation 166. In the middle region, an SEG p-GaN gate E-mode AlGaN/GaN HEMT M2 is formed. This SEG p-GaN gate E-mode AlGaN/GaN HEMT M2 includes a p-GaN inverted trapezoidal gate structure 26. In addition, although the 2DEG is formed at the junction i-AlₓGaN/i-GaN of the i-GaN channel layer 15, due to the existence of the p-GaN inverted trapezoidal gate structure 26, the 2DEG below the p-GaN inverted trapezoidal gate structure 26 in the i-GaN channel layer 15 will be depleted, giving a depletion region 262 without 2DEG. In the right region, a D-mode AlGaN/GaN HEMT with gate dielectric layer M3 is formed. Top view of M1-M3 in this embodiment is shown in FIG. 18B.

Embodiment 8: As shown in FIG. 19A-1 and FIG. 19A-2, a hybrid E-mode AlGaN/GaN HEMT formed by the etched p-GaN gate metal E-mode AlGaN/GaN HEMT using a fluorine lightly implanted D-mode AlGaN/GaN HEMT without gate dielectric layer as the gate protection device cascading to a D-mode AlGaN/GaN HEMT with gate dielectric layer to increase the off-state breakdown voltage of the hybrid E-mode AlGaN/GaN HEMT.

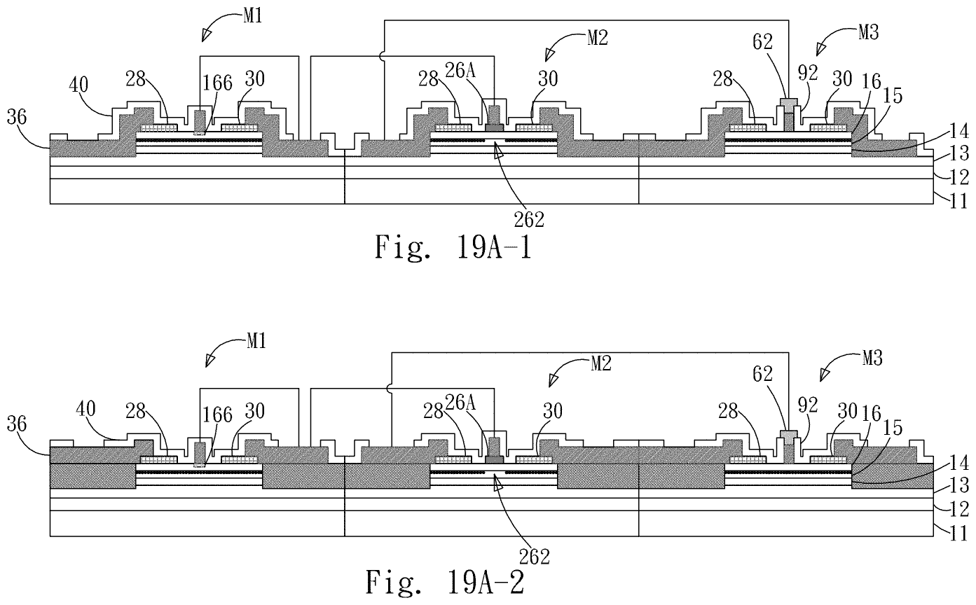

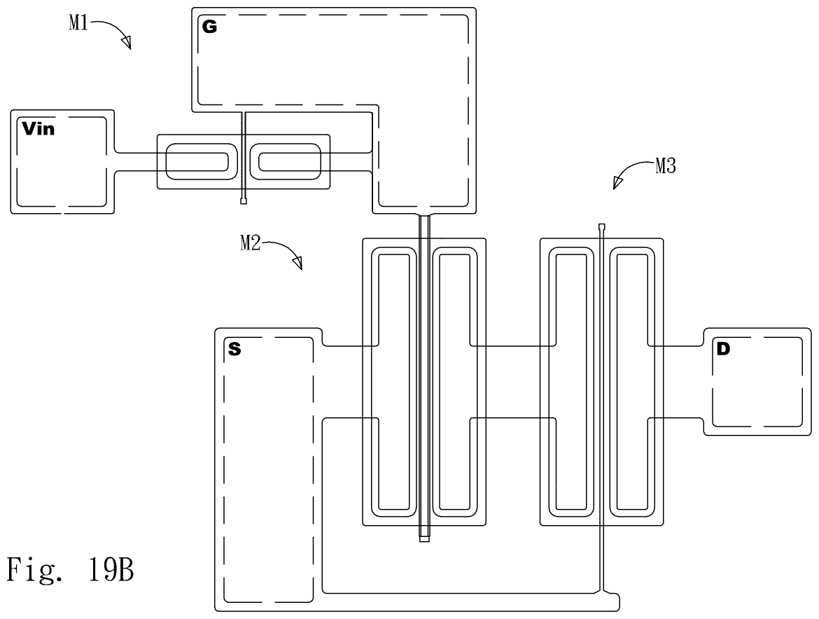

As shown in FIG. 19A-1 and FIG. 19A-2, the hybrid E-mode AlGaN/GaN HEMT according to Embodiment 8 comprises the epitaxial structure of AlGaN/GaN designed according to the present invention and is divided into a left region, a middle region, and a right region. In the left region, a fluorine lightly implanted D-mode AlGaN/GaN HEMT without gate dielectric layer M1 is formed with the fluorine implantation 166. In the middle region, an etched p-GaN gate E-mode AlGaN/GaN HEMT M2 is formed. In addition, although the 2DEG 152 is formed at the junction i-AlₓGaN/i-GaN of the i-GaN channel layer 15, due to the existence of the etched p-GaN gate structure 26A, the 2DEG 152 below the p-GaN 26A in the i-GaN channel layer 15 will be depleted, giving a depletion region 262 without 2DEG. In the right region, a D-mode AlGaN/GaN HEMT with gate dielectric layer M3 is formed. Top view of M1-M3 in this embodiment is shown in FIG. 19B.

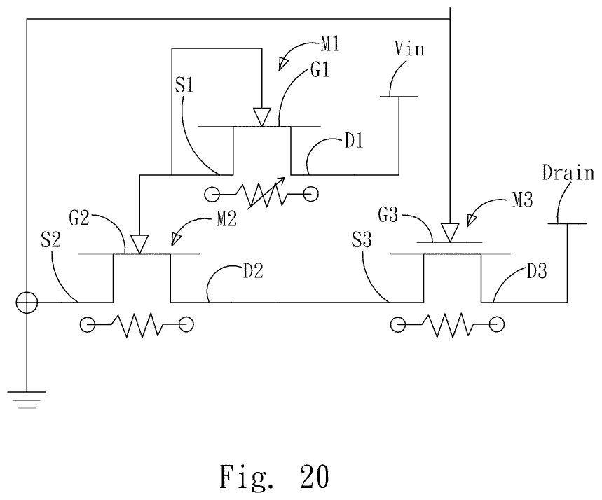

An equivalent circuit of Embodiment 6 to 8 can be expressed in the schematic diagram as shown in FIG. 20.

1. An epitaxial structure of hybrid E-mode AlGaN/GaN HEMT, comprising:
an epitaxial structure of Ga-face AlGaN/GaN, divided into a first region and a second region;
a first thin p-GaN gate depletion-mode (D-mode) AlGaN/GaN HEMT, formed in said first region; and
a p-GaN E-mode AlGaN/GaN HEMT, formed in said second region, including a p-GaN inverted trapezoidal gate structure, the 2DEG below said p-GaN inverted trapezoidal gate structure being depleted, a source and a gate of said first D-mode AlGaN/GaN HEMT electrically connected to each other, the Vgs of said p-GaN E-mode AlGaN/GaN HEMT being 5\tilde{ }10V, a saturation current corresponding to a Vgs of said first D-mode AlGaN/GaN HEMT decided by a gate width of said first D-mode AlGaN/GaN HEMT when said first D-mode AlGaN/GaN HEMT is in saturation;
where said epitaxial structure of Ga-face AlGaN/GaN includes:
a silicon substrate;
a buffer layer (C-doped), located on the silicon substrate;
an i-GaN (C-doped) buffer layer, located on the buffer layer (C-doped);
an i-AlyGaN buffer layer, located on the i-GaN (C-doped) layer;
an i-GaN channel layer, located on the i-AlyGaN buffer layer, said 2DEG formed in said i-GaN channel layer; and
an i-AlxGaN layer, located on the i-GaN channel layer, where x=0.1\tilde{ }0.3 and y=0.05\tilde{ }0.75

2. The epitaxial structure of hybrid E-mode AlGaN/GaN HEMT of claim 1, wherein a thickness of a gate structure of the first thin p-GaN gate depletion-mode (D-mode) AlGaN/GaN HEMT is smaller than a thickness of the p-GaN inverted trapezoidal gate structure of the p-GaN E-mode AlGaN/GaN HEMT.

3. An epitaxial structure of hybrid E-mode AlGaN/GaN HEMT, comprising:
an epitaxial structure of Ga-face AlGaN/GaN, divided into a first region and a second region;
a first thin p-GaN gate depletion-mode (D-mode) AlGaN/GaN HEMT, formed in said first region; and
a p-GaN E-mode AlGaN/GaN HEMT, formed in said second region, including an etched p-GaN gate structure, a 2DEG below said etched p-GaN gate structure being depleted, said etched p-GaN gate structure connected electrically to a source and a gate of said first D-mode AlGaN/GaN HEMT, a Vgs of said p-GaN E-mode AlGaN/GaN HEMT being 5\tilde{ }10V, a saturation current corresponding to a Vgs of said first D-mode AlGaN/GaN HEMT decided by a gate width of said first D-mode AlGaN/GaN HEMT when said first D-mode AlGaN/GaN HEMT is in saturation;
where said epitaxial structure of Ga-face AlGaN/GaN includes:
a silicon substrate;
a buffer layer (C-doped), located on the silicon substrate;
an i-GaN (C-doped) buffer layer, located on the buffer layer (C-doped);
an i-AlyGaN buffer layer, located on the i-GaN (C-doped) layer;
an i-GaN channel layer, located on the i-AlyGaN buffer layer, said 2DEG formed in said i-GaN channel layer; and
an i-AlxGaN layer, located on the i-GaN channel layer, where x=0.1\tilde{ }0.3 and y=0.05\tilde{ }0.75.

4. The epitaxial structure of hybrid E-mode AlGaN/GaN HEMT of claim 3, wherein a thickness of a gate structure of the first thin p-GaN gate depletion-mode (D-mode) AlGaN/GaN HEMT is smaller than a thickness of the p-GaN inverted trapezoidal gate structure of the p-GaN E-mode AlGaN/GaN HEMT.

5. An epitaxial structure of hybrid E-mode AlGaN/GaN HEMT, comprising:
an epitaxial structure of Ga-face AlGaN/GaN, divided into a first region and a second region;
a fluorine lightly implanted depletion-mode (D-mode) AlGaN/GaN HEMT, formed in said first region; and
a p-GaN E-mode AlGaN/GaN HEMT, formed in said second region, including a p-GaN inverted trapezoidal gate structure, the 2DEG below said p-GaN inverted trapezoidal gate structure being depleted, said p-GaN inverted trapezoidal gate structure connected electrically to a source and a gate of said first D-mode AlGaN/GaN HEMT, the Vgs of said p-GaN E-mode AlGaN/GaN HEMT being 5\tilde{ }10V, a saturation current corresponding to a Vgs of said first D-mode AlGaN/GaN HEMT decided by a gate width of said first D-mode AlGaN/GaN HEMT when said first D-mode AlGaN/GaN HEMT is in saturation;
where said epitaxial structure of Ga-face AlGaN/GaN includes:
a silicon substrate;
a buffer layer (C-doped), located on the silicon substrate;
an i-GaN (C-doped) buffer layer, located on the buffer layer (C-doped);
an i-AlyGaN buffer layer, located on the i-GaN (C-doped) layer;
an i-GaN channel layer, located on the i-AlyGaN buffer layer, said 2DEG formed in said i-GaN channel layer; and
an i-AlxGaN layer, located on the i-GaN channel layer, where x=0.1\tilde{ }0.3 and y=0.05\tilde{ }0.75

6. The epitaxial structure of hybrid E-mode AlGaN/GaN HEMT of claim 5, wherein the fluorine lightly implanted depletion-mode (D-mode) AlGaN/GaN HEMT has a fluorine implantation formed under a gate metal.

7. An epitaxial structure of hybrid E-mode AlGaN/GaN HEMT, comprising:
an epitaxial structure of Ga-face AlGaN/GaN, divided into a first region and a second region;
a fluorine lightly implanted depletion-mode (D-mode) AlGaN/GaN HEMT, formed in said first region; and
a p-GaN E-mode AlGaN/GaN HEMT, formed in said second region, including an etched p-GaN gate structure, a 2DEG below said etched p-GaN gate structure being depleted, said etched p-GaN gate structure connected electrically to a source and a gate of said first D-mode AlGaN/GaN HEMT, a Vgs of said p-GaN E-mode AlGaN/GaN HEMT being 5\tilde{ }10V, a saturation current corresponding to a Vgs of said first D-mode AlGaN/GaN HEMT decided by a gate width of said first D-mode AlGaN/GaN HEMT when said first D-mode AlGaN/GaN HEMT is in saturation;
where said epitaxial structure of Ga-face AlGaN/GaN includes:
a silicon substrate;
a buffer layer (C-doped), located on the silicon substrate;
an i-GaN (C-doped) buffer layer, located on the buffer layer (C-doped);
an i-AlyGaN buffer layer, located on the i-GaN (C-doped) layer;
an i-GaN channel layer, located on the i-AlyGaN buffer layer, said 2DEG formed in said i-GaN channel layer; and
an i-AlxGaN layer, located on the i-GaN channel layer, where x=0.1\tilde{ }0.3 and y=0.05\tilde{ }0.75.

8. The epitaxial structure of hybrid E-mode AlGaN/GaN HEMT of claim 7, wherein the fluorine lightly implanted depletion-mode (D-mode) AlGaN/GaN HEMT has a fluorine implantation formed under a gate metal.
